(19) United States
(12) Patent Application Publication
(10) Pub. No.: US 2026/0068738 A1
(43) Pub. Date: Mar. 5, 2026

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Ming-Tsu Chung, Hsinchu City (TW); Yung-Chi Lin, New Taipei City (TW); Kuo-Chiang Ting, Hsinchu City (TW); Jyu-Horng Shieh, Hsin-Chu (TW); Yen-Ming Chen, Hsin-Chu County (TW)

(73) Assignee: Taiwan Semiconductor Manufacturing Company, Ltd., Hsinchu (TW)

(21) Appl. No.: 18/817,204

(22) Filed: Aug. 27, 2024

(51) Int. Cl. H01L 23/31; H01L 23/00; H01L 23/498; H01L 25/065

(52) U.S. Cl. CPC H01L 23/3135

(57) ABSTRACT

A semiconductor device and a method of forming a semiconductor device are provided. The semiconductor device includes a first die, a diamond layer and an encapsulant. The diamond layer is disposed on the first die. The encapsulant is disposed on the first die, wherein the encapsulant encapsulates the diamond layer.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that may be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1I are schematic cross-sectional views of various stages in a method of forming a semiconductor device according to some embodiments.

FIG. 2A to FIG. 2E are schematic cross-sectional views of various stages in a method of forming a semiconductor device according to some embodiments.

FIG. 3A to FIG. 3C are schematic cross-sectional views of various stages in a method of forming a semiconductor device according to some embodiments.

FIG. 4A to FIG. 4F are schematic cross-sectional views of various stages in a method of forming a semiconductor device according to some embodiments.

FIG. 5 is a schematic cross-sectional view of a semiconductor device according to some embodiments.

FIG. 6 is a schematic cross-sectional view of a semiconductor device according to some embodiments.

FIG. 7 is a schematic cross-sectional view of a semiconductor device according to some embodiments.

FIG. 8 is a schematic cross-sectional view of a semiconductor device according to some embodiments.

FIG. 9 is a schematic cross-sectional view of a semiconductor device according to some embodiments.

FIG. 10 is a schematic cross-sectional view of a semiconductor device according to some embodiments.

FIG. 11A to FIG. 11C are schematic cross-sectional views of various stages in a method of forming a semiconductor device according to some embodiments.

FIG. 12A to FIG. 12H are schematic cross-sectional views of various stages in a method of forming a semiconductor device according to some embodiments.

FIG. 13 illustrates a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

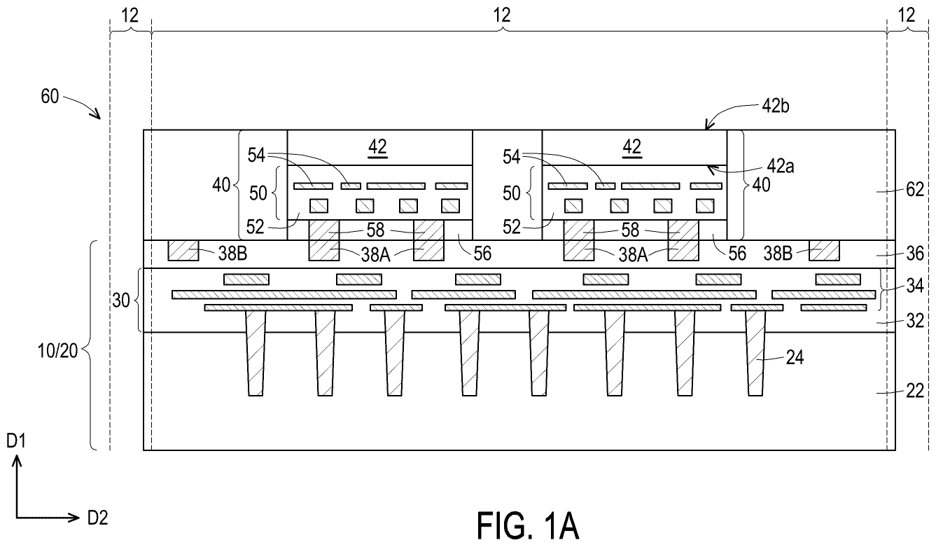

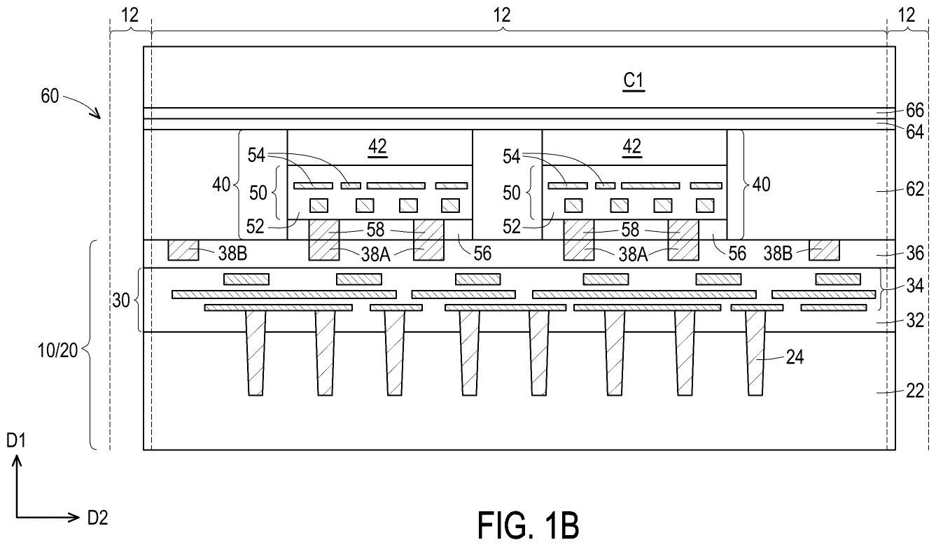

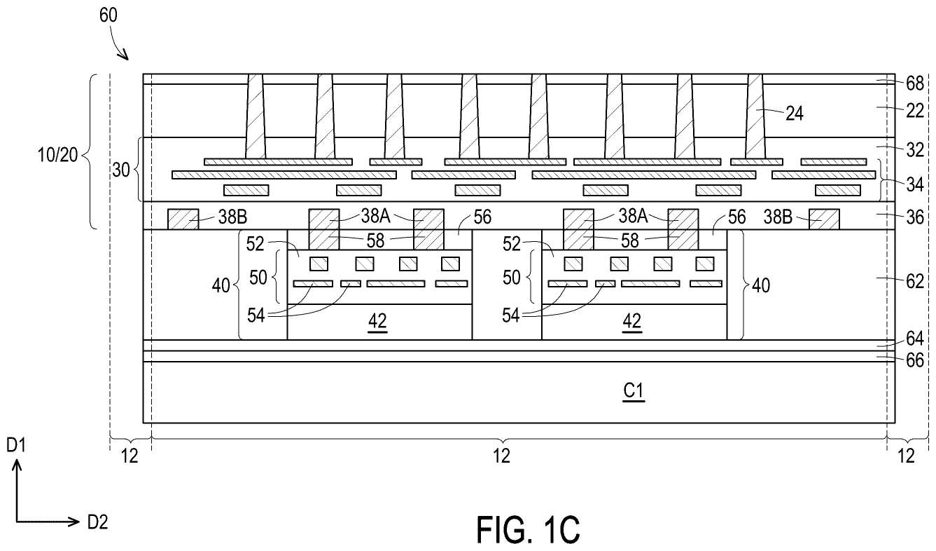

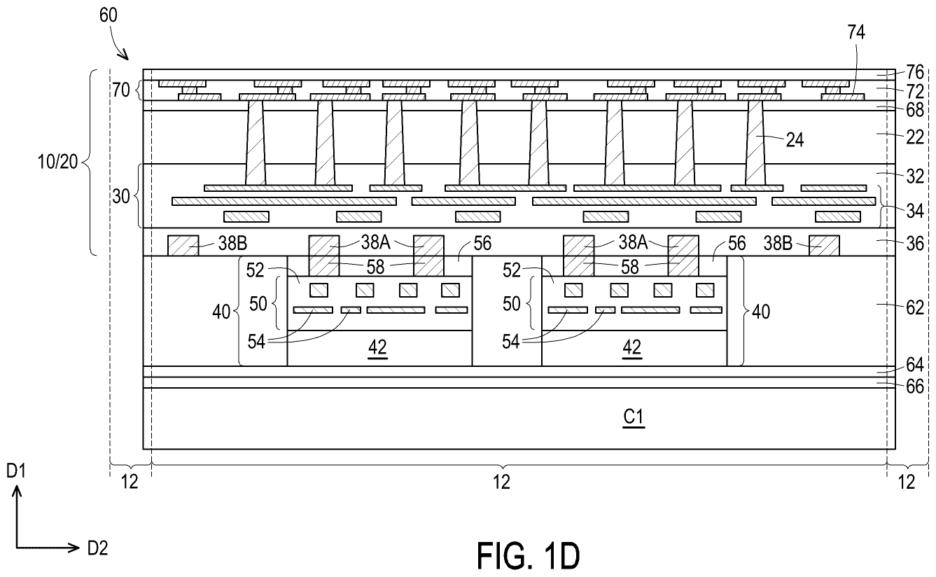

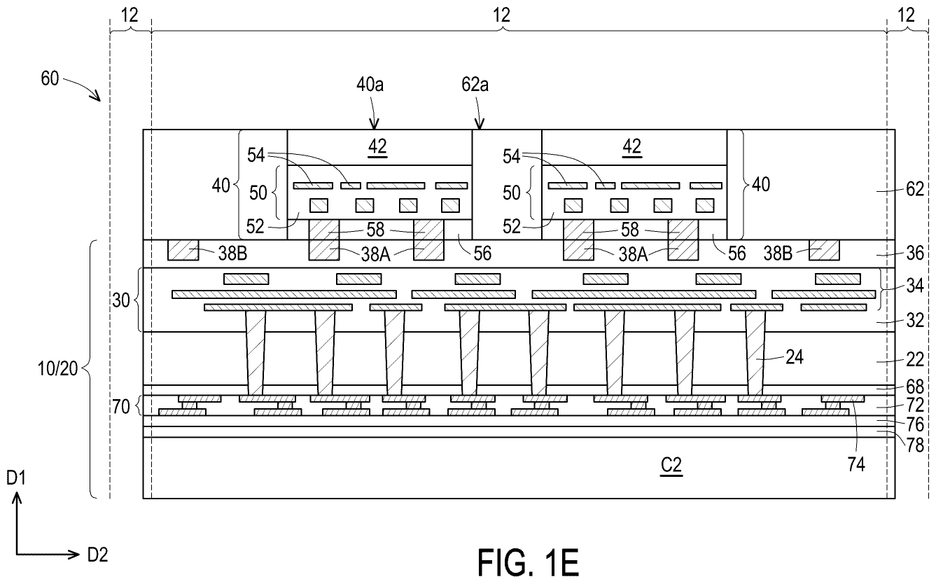

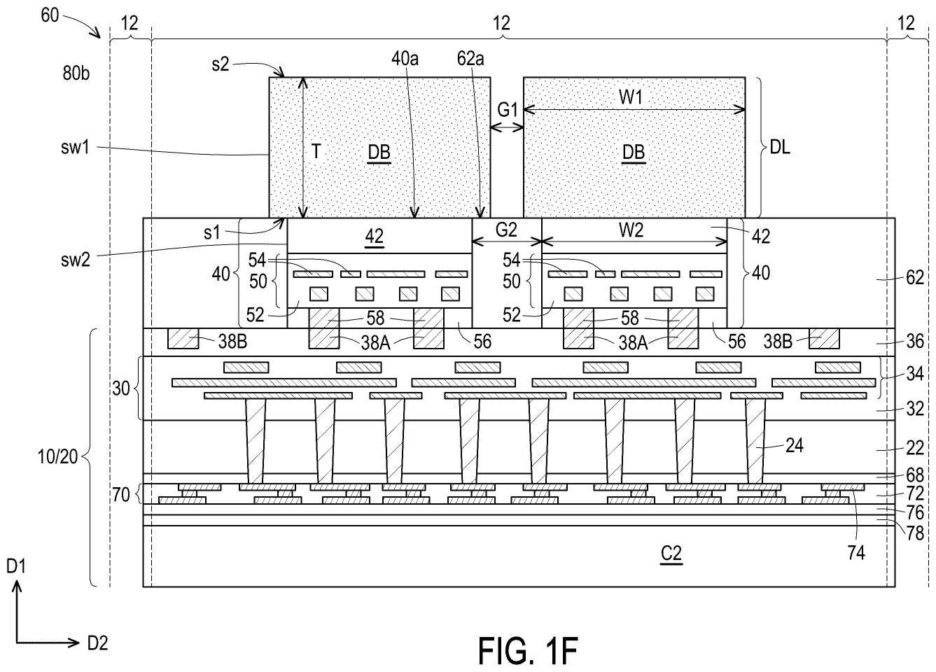

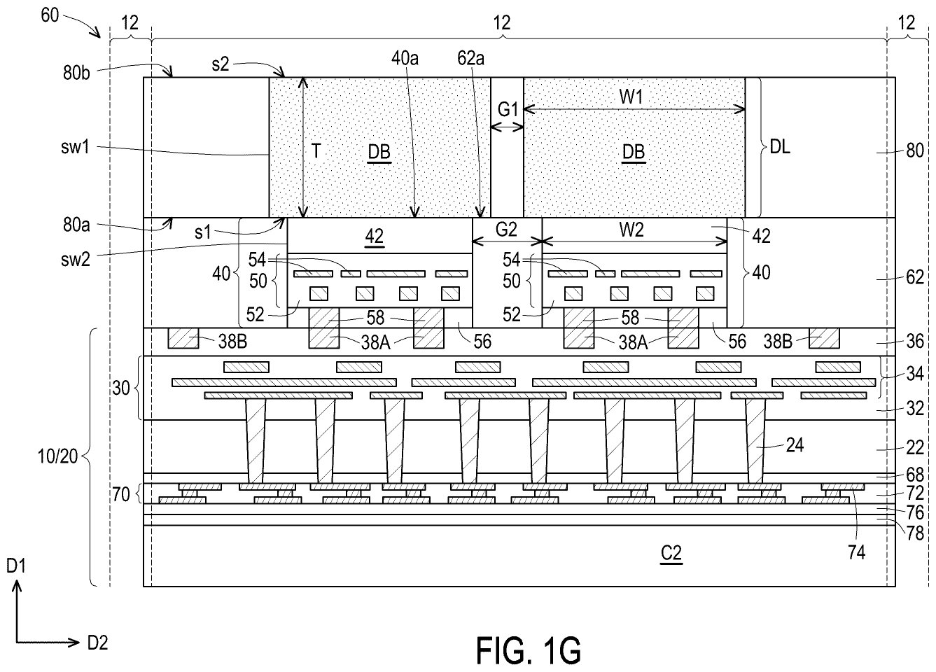

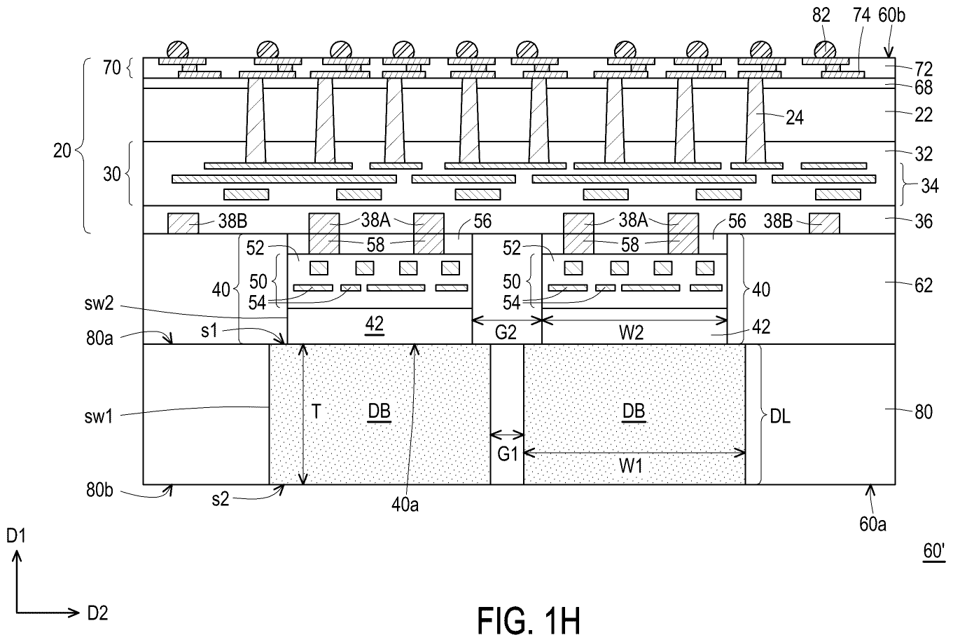

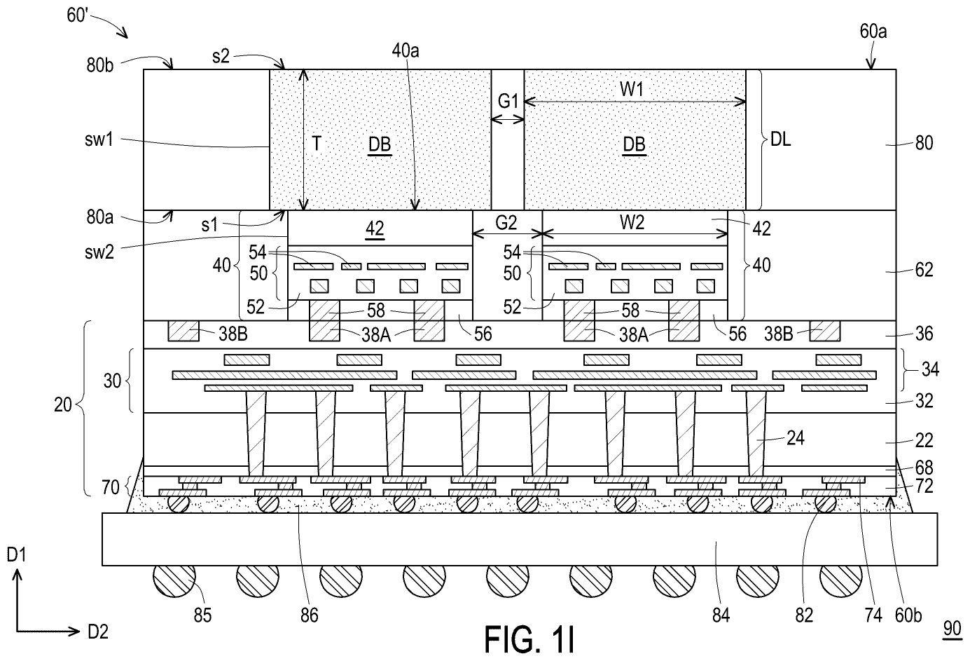

FIG. 1A to FIG. 1I are schematic cross-sectional views of various stages in a method of forming a semiconductor device according to some embodiments.

Referring to FIG. 1A, a package component 10 is provided. The package component 10 has a first surface (e.g., a front-side surface) and a second surface (e.g., a backside surface) opposite to the first surface. The package component 10 (also referred to as a bottom wafer) may include a plurality of die regions 12 that are singulated in subsequent steps to form a plurality of dies 20. For example, the die regions 12 are separated by scribe line regions (not shown) therebetween. In some embodiments, the dies 20 have the same size (e.g., same height and/or area). In alternative embodiments, the dies 20 have different sizes (e.g., different heights and/or areas). The dies 20 may be of the same type or different types. Each die 20 may be a logic die (e.g., central processing unit (CPU), graphics processing unit (GPU), system-on-chips (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or a combination thereof. The die 20 will be packaged in subsequent processing to form a package. A thickness of the die 20 along a direction D1 is in a range of 600μm and 900μm, for example. The direction D1 is a vertical direction (e.g., z direction), and a direction D2 substantially perpendicular to the direction D1 is a horizontal direction (e.g., x direction or y direction), for example. However, the disclosure is not limited thereto. The die 20 may have any suitable thickness. In some embodiments, the die 20 is also referred to as device die.

The die 20 may include a substrate 22 and an interconnect structure 30. The substrate 22 may be a semiconductor substrate such as a substrate of silicon, doped or undoped, or an active layer of a semiconductor-on-insulator (SOI) substrate. The substrate 22 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multi-layered or gradient substrates, may also be used. The substrate 22 has a first surface 22a and a second surface 22b opposite to the first surface 22a. The first surface 22a is an active surface and the second surface 22b is a non-active surface, for example.

Integrated circuit devices (not shown) may be formed at the first surface (e.g., active surface) 22a of the substrate 22. The integrated circuit devices may include transistors such as Complementary Metal-Oxide Semiconductor (CMOS) transistors, resistors, capacitors, diodes, and/or the like.

In some embodiments, the substrate 22 includes through vias 24. The through vias 24 are also referred to as through-silicon vias (TSVs) or through-semiconductor vias (also TSVs). The through vias 24 may be electrically connected to the integrated circuit devices. In some embodiments, the through vias 24 extend from the first surface 22a of the substrate 22 (or a level higher than the first surface 22a of the substrate 22 as shown in FIG. 1A) to an intermediate level of the substrate 22. The intermediate level of the substrate 22 is between the first surface 22a and the second surface 22b of the substrate 22. Each of the through vias 24 may be surrounded by a dielectric isolation layer (not shown), which is used for electrically insulating the corresponding through via 24 from the substrate 22.

The interconnect structure 30 is over the first surface 22a of the substrate 22 and the integrated circuit device. The interconnect structure 30 may include an inter-layer dielectric (ILD) (not separately illustrated) filling the spaces between the gate stacks of transistors (not shown) in the integrated circuit devices. The ILD may include one or more dielectric layers formed of materials such as phospho-silicate glass (PSG), boro-silicate glass (BSG), boron-doped phospho-silicate glass (BPSG), undoped silicate glass (USG), or the like. The interconnect structure 30 may further include conductive plugs (not separately illustrated) in the ILD. The conductive plugs are used to electrically connect the integrated circuit devices to overlying conductive lines and vias. For example, when the integrated circuit devices are transistors, the conductive plugs electrically connect to the gates and the source and drain regions of the transistors. The conductive plugs may be formed of tungsten, cobalt, nickel, copper, silver, gold, aluminum, the like, or a combination thereof.

In some embodiments, the interconnect structure 30 include one or more dielectric layer(s) 32 and conductive features 34 in the dielectric layer(s) 32. The dielectric layer 32 may include a low-k dielectric material such as PSG, BSG, BPSG, USG, or the like. The dielectric layer 32 may further include an oxide such as silicon oxide or aluminum oxide; a nitride such as silicon nitride; a carbide such as silicon carbide; the like; or a combination thereof such as silicon oxynitride, silicon oxycarbide, silicon carbonitride, silicon oxycarbonitride or the like. Other dielectric material may also be used, such as polymer such as polybenzoxazole (PBO), polyimide, a benzocyclobuten (BCB) based polymer, or the like. The conductive features 34 may include conductive vias and/or conductive lines to interconnect the integrated circuit devices of the substrate 22. The conductive feature 34 may be formed of a conductive material, such as a metal, such as copper, cobalt, aluminum, gold, a combination thereof, or the like. Each conductive feature 34 may be formed in and/or on the dielectric layer 32. The interconnect structure 30 may be formed by a damascene process, such as a single damascene process, a dual damascene process, or the like.

In some embodiments, the die 20 further includes a bonding layer 36. The bonding layer 36 is formed over the interconnect structure 30. The bonding layer 36 may include silicon-containing dielectric material such as SiO, SiC, SiN, SiON, SiOC, SiCN, SiOCN, the like, or a combination thereof. The bonding layer 36 may be planarized using a CMP process or a mechanical grinding process so that its outmost surface (e.g., top surface) is planar.

Bonding pads 38A, 38B may be formed in the bonding layer 36. The bonding pads 38A, 38B may include copper, and may be formed through a damascene process. The bonding layer 36 and the bonding pads 38A, 38B may be planarized using a CMP process or a mechanical grinding process so that its outmost surface (e.g., top surface) is planar. The bonding pads 38A are electrically connected to the underlying conductive features 34 such as conductive lines and vias, the integrated circuit devices, and the through vias 24. The bonding pads 38A may be also referred to as active bonding pads since they are used for bonding to the overlaying top die, and are electrically connected to the conductive features 34 and possibly the through vias 24. The bonding pads 38B may be also referred to as dummy bonding pads since they are used for reducing pattern loading effect in the process such as CMP process. The bonding pads 38B may be electrically floating.

As shown in FIG. 1A, dies 40 (also referred to as top dies) are bonded to the dies 20 (also referred to as bottom dies) in the package component 10 along the direction D1. In some embodiments, each of the dies 40 is a logic die such as a Central Processing Unit (CPU) die, a microcontroller (MCU) die, an input-output (IO) die, a BaseBand die, or the like. The dies 40 may also include memory dies. In some embodiments, the die 40 may generate more heat than the die 20. However, the disclosure is not limited thereto. A width of the die 40 along the direction D2 is smaller than a width of the die 20 along the direction D2, for example. The die 40 may have a similar structure to the die 20. For example, the die 40 includes a substrate 42, an interconnect structure 50, a bonding layer 56 and bonding pads 58. The substrate 42 may be a semiconductor substrate such as a substrate of silicon, doped or undoped, or an active layer of a semiconductor-on-insulator (SOI) substrate. The substrate 42 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multi-layered or gradient substrates, may also be used. The substrate 42 has a first surface 42a and a second surface 42b opposite to the first surface 42a. The first surface 42a is an active surface and the second surface 42b is a non-active surface, for example. In some embodiments, the die 40 is also referred to as device die.

The interconnect structure 50 may be electrically connected to integrated circuit devices such as active devices and passive devices in the die 40. The interconnect structure 50 include one or more dielectric layer(s) 52 and conductive features 54 in the dielectric layer(s) 52. The dielectric layers 52 may include low-k dielectric materials such as PSG, BSG, BPSG, USG, or the like. The dielectric layers 52 may further include oxides such as silicon oxide or aluminum oxide; nitrides such as silicon nitride; carbides such as silicon carbide; the like; or a combination thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The conductive features 54 may include conductive vias and/or conductive lines to interconnect the integrated circuit devices of the substrate 42. The conductive features 54 may be formed of a conductive material, such as a metal, such as copper, cobalt, aluminum, gold, a combination thereof, or the like. Each conductive feature 54 may be formed in and/or on the dielectric layer 52. The interconnect structure 50 may be formed by a damascene process, such as a single damascene process, a dual damascene process, or the like.

The bonding layer 56 is formed over the interconnect structure 50. The bonding layer 56 may include silicon-containing dielectric material such as SiO, SiC, SiN, SiON, SiOC, SiCN, SiOCN, the like, or a combination thereof. The bonding pads 58 may be formed in the bonding layer 56. The bonding pads 58 are electrically connected to the underlying conductive features 54 such as conductive lines and vias and the integrated circuit devices and used for bonding to the overlaying bottom die. The bonding pads 58 may include copper, and may be formed through a damascene process. The bonding layer 56 and the bonding pads 58 may be planarized using a CMP process or a mechanical grinding process so that its surface is planar.

The dies 40 and the die 20 may be bonded through a hybrid bonding. For example, the bonding pads 58 are bonded to the bonding pads 38A through metal-to-metal direct bonding. The metal-to-metal direct bonding may include copper-to-copper direct bonding. Furthermore, the bonding layers 56 are bonded to the bonding layer 36 through fusion bonding, for example, with Si—O—Si bonds being generated. In some embodiments in which the package component 10 is a wafer, the bonding is also referred to as a chip on wafer bonding. Furthermore, the bonded structure illustrated in FIG. 1A is also referred to as reconstructed component 60 or reconstructed wafer hereinafter.

Then, an encapsulant 62 is formed over the die 20 to encapsulate the dies 40. In some embodiments, the encapsulant 62 fills the gap(s) between the dies 40. In some embodiments, the encapsulant 62 includes a dielectric material such as an oxide (e.g., silicon oxide) or the like, and the encapsulant 62 is formed by a depositing process or a suitable process for gap filling. In alternative embodiments, the encapsulant 62 includes a molding compound or the like. The molding compound may include a base material and filler particles in the base material, the base material may include a polymer, a resin, and/or an epoxy, and the filler particles may include silica, aluminum oxide, silicon oxide and the like. In such embodiments, the encapsulant 62 is formed by dispensing a molding compound in a flowable form, and curing the molding compound as a solid. In some embodiments, a planarized process such as CMP is performed on the material of the encapsulant 62 until the dies 40 are exposed. Thus, a surface of the encapsulant 62 is substantially coplanar with surfaces of the dies 40, for example.

Referring to FIG. 1B, a carrier substrate C1 is bonded to the reconstructed component 60. In some embodiments, the carrier substrate C1 is a silicon substrate, a glass substrate, a ceramic substrate or any suitable carrier for carrying a semiconductor wafer or a reconstituted wafer for the manufacturing method of the package structure. For example, the carrier substrate C1 is a silicon substrate. In some embodiments, the carrier substrate C1 is coated with at least one debond layer 66. The material of the debond layer 66 may be any material suitable for bonding and debonding the carrier substrate C1 from the above layer(s) or any wafer(s) disposed thereon. In some embodiments, a dielectric layer 64 is further formed between the debond layer 66 and the encapsulant 62 and the dies 40. The dielectric layer 64 may be formed on the surfaces of the encapsulant 62 and the dies 40 after forming the encapsulant 62. In some embodiments, the dielectric layer 64 is formed of a photo-sensitive material such as polybenzoxazole (PBO), polyimide, benzocyclobutene (BCB), or the like. The dielectric layer 64 may be formed by spin coating, lamination, CVD, the like, or a combination thereof. The dielectric layer 64 is optional and may be omitted based on the demand, so that the disclosure is not limited thereto. In some embodiments, the debond layer 66 is sandwiched between the dielectric layer 64 and the carrier substrate C1. The debond layer 66 may include a dielectric material made of an epoxy-based thermal-release material, which loses its adhesive property when heated, such as a light-to-heat-conversion (LTHC) release coating film. The LTHC release coating film has good chemical resistance, and such layer enables room temperature debonding from the carrier substrate C1 by applying laser irradiation, for example. The debond layer 66 may include an adhesive material such as die attach film (DAF). The debond layer 66 may include a dielectric material made of an ultra-violet (UV) glue, which loses its adhesive property when exposed to UV lights. In some embodiments, the debond layer 66 includes a LTHC release coating film and a DAF disposed between the LTHC release coating film and the dielectric layer 64. In some embodiments, the debond layer 66 is dispensed as a liquid and cured, or is a laminate film laminated onto the carrier substrate C1, or the like. The debond layer 66 may have a first surface contacting the carrier substrate C1 and a second surface opposite to the first surface, and second surface may be levelled and may have a high degree of coplanarity.

Referring to FIG. 1C, after bonding to the carrier substrate C1, the structure shown in FIG. 1B may be turned upside down. Then, the substrate 22 of the die 20 is thinned, so as to expose the through vias 24, for example. In some embodiments, the substrate 22 is partially removed by a thinning process such as a CMP process or a mechanical grinding process. After performing the thinning process, the through vias 24 may be exposed. Then, the substrate 22 of the die 20 may be recessed to form recesses, and some portions (the illustrated top portions) of the through vias 24 protrude beyond the substrate 22. In some embodiments, as shown in FIG. 1C, a dielectric isolation layer 68 is then be formed. The formation of the dielectric isolation layer 68 may include a deposition process to deposit a dielectric layer into the recesses generated by recessing the substrate 22, so that the protruding portions of the through vias 24 are in the dielectric layer, followed by a planarization process. The portions of the dielectric layer beyond the through vias 24 are removed, and the remaining portions of the dielectric layer form the dielectric isolation layer 68, which becomes parts of dies 20 and the package component 10. After the thinning process, the thickness of the die 20 along the direction D1 is in a range of 50μm and 100μm, for example.

Referring to FIG. 1D, a redistribution layer (RDL) structure 70 is formed on the dies 20 and 40 over the carrier substrate C1. In some embodiments, the RDL structure 70 includes dielectric layers 72 and RDLs 74 in the dielectric layers 72. The RDL structure 70 may be formed by forming the dielectric layer 72, forming a plurality of openings in the dielectric layer 72 and forming the RDL 74 in the dielectric layer 72. The dielectric layer 72 may include an organic material such as PBO, polyimide, BCB or the like, an inorganic material such as silicon oxide, silicon nitride or the like. The RDL 74 may be formed by a damascene process, such as a single damascene process, a dual damascene process, or the like. In some embodiments, a dielectric layer 76 is formed over the RDL structure 70. In some embodiments, the dielectric layer 76 is similar to the dielectric layer 64, so the detailed description thereof is omitted herein.

Referring to FIG. 1E, a carrier substrate C2 is bonded to the reconstructed component 60 with a debond layer 78 therebetween. In some embodiments, the carrier substrate C2 is bonded to the reconstructed component 60 through the debond layer 78 and the dielectric layer 76 between the reconstructed component 60 and the debond layer 78. In some embodiments, the carrier substrate C2 and the debond layer 78 are similar to the carrier substrate C1 and the debond layer 66, so the detailed description thereof is omitted herein. For example, the carrier substrate C2 is a silicon substrate. After the carrier substrate C2 is bonded, the carrier substrate C1 may be removed. In some embodiments, the carrier substrate C1 is debonded and is separated from the dies 40 and the encapsulant 62. In some embodiments in which the debond layer 66 includes a LTHC release layer, the debonding process includes projecting a light such as a laser light or an UV light on the debond layer 66 so that the carrier substrate C1 may be removed along with the debond layer 66 and the dielectric layer 64. In some embodiments in which the debond layer 66 includes a DAF, a cleaning process may be applied to remove the DAF after the carrier substrate C1 is removed. In alternative embodiments, the carrier substrate C1 is removed by a grinding process, CMP process or the like. After the removal process, surfaces (e.g., backside surfaces) 40a of the dies 40 and a surface 62a of the encapsulant 62 are revealed or exposed. For example, the substrates 42 of the dies 40 are revealed or exposed.

Referring to FIG. 1F, a diamond layer DL is disposed over the dies 40. In some embodiments, the diamond layer DL includes at least one diamond block DB. For example, the diamond layer DL includes a plurality of diamond blocks DB. Diamond as used herein may refer to diamond or diamond like carbon (DLC) coating. The diamond has thermal conductivity greater than that of silicon. Thermal conductivity of silicon is about 156 W/mK, thermal conductivity of a diamond is about 600 or higher, for example, between about 1500 W/mK and about 3000 W/mK, and Thermal conductivity of the diamond like carbon coating is between about 400 W/mK and about 1000 W/mK. In other words, the thermal conductivity of the diamond layer DL may be large than the thermal conductivity of the substrate 22, 42 of the dies 20, 40 and entirety of the dies 20, 40. Therefore, in some embodiments, the diamond layer DL is also referred to as heat dissipation layer, and the diamond block DB is also referred to as heat dissipation block. The diamond layer DL and the diamond block DB may be also referred to as diamond substrate. A thickness T of the diamond layer DL (e.g., diamond block DB) along the direction D1 is in a range of 300μm to 1000μm, for example.

In some embodiments, the diamond layer DL is formed on the dies 40 over the carrier substrate C2. The diamond blocks DB may be formed on the dies 40 respectively, and gap(s) G1 are formed between the diamond blocks DB. In some embodiments, the diamond layer DL is stacked on and thermally coupled to the dies 40. For example, the diamond blocks DB cover exposed surfaces (e.g., backside surfaces) 40a of the dies 40 respectively. In such embodiments, the diamond block DB may have the size (e.g., width, length and area) corresponding to the size (e.g., width, length and area) of the underlying die 40. For example, a width W1 of the diamond block DB along the direction D2 is larger than a width W2 of the underlying die 40 and thus the diamond block DB covers the underlying die 40 entirely. A sidewall sw1 of the diamond block DB may extend beyond a sidewall sw2 of the die 40, and the gap G1 between the diamond blocks DB is smaller than a gap G2 between the dies 40. The gap G1 between the diamond blocks DB is larger than 50μm, for example. In some embodiments, both opposing sidewalls sw1 of the diamond block DB are offset from the respective sidewalls sw2 of the underlying die 40, and the opposing sidewalls sw2 of the diamond block DB are disposed between the opposing sidewalls sw1 of the diamond block DB. However, the disclosure is not limited thereto. In alternative embodiments, only one of the sidewalls sw2 of the underlying die 40 is disposed between the sidewalls sw1 of the diamond block DB. In some embodiments, the diamond block DB covers a portion of the encapsulant 62 between the dies 40. For example, the diamond block DB covers a portion of the surface 62a of the encapsulant 62 between the dies 40. In some embodiments, the diamond block DB physically contacts both the die 40 and the encapsulant 62. However, the disclosure is not limited thereto.

The diamond layer DL (e.g., diamond block DB) has a surface s1 to be bonded to the die 40 and a surface s2 opposite to the surface s1. For example, the surface s1 of the diamond layer DL (e.g., diamond block DB) faces the surface 40a of the die 40. In some embodiments, the diamond layer DL is disposed over the dies 40 by a pick-and-place process. For example, the diamond blocks DB are picked and placed onto the surfaces 40a (e.g., backside surfaces) of the dies 40 respectively by a pick-and-place process. The pick-and-place process is performed under a pressure lower than about 10-7 torr, for example. Before disposing the diamond layer DL (e.g., diamond block DB), a treatment process such as a plasma treatment process may be performed on the surface s1 of the diamond layer DL (e.g., diamond block DB) and/or the surface 40a of the die 40 (e.g., substrate 42). The treatment process may improve the adherence between the diamond layer DL (e.g., diamond block DB) and the die 40 (e.g., substrate 42). In some embodiments, the plasma treatment process to the diamond layer DL (e.g., diamond block DB) includes helium (He), argon (Ar), or a combination thereof. The plasma treatment may include use of a plasma source with a power between about 15 W and about 500 W, and lasts between about 2 seconds and about 60 seconds. In some embodiments, the plasma treatment process to the substrate 42 of the die 40 includes helium (He), argon (Ar), or a combination thereof. The plasma treatment may include use of a plasma source with a power between about 15 W and about 500 W, and lasts between about 2 seconds and about 60 seconds. In alternative embodiments (which will be described below), an additional layer such as bonding layer or adhesive layer is further disposed between the diamond layer DL (e.g., diamond block DB) and the die 40 and/or between the diamond layer DL (e.g., diamond block DB), to improve the adherence between the diamond layer DL (e.g., diamond block DB) and the die 40 (e.g., substrate 42).

Referring to FIG. 1G, an encapsulant 80 is formed to encapsulate the diamond layer DL. In some embodiments, the encapsulant 80 is formed over the carrier substrate C2 to encapsulate the diamond blocks DB and fills the gap(s) G1 between the diamond blocks DB. Each diamond block DB is surrounded by the encapsulant 80, for example. The material of the encapsulant 80 may be the same as or different from a material of the encapsulant 62. The encapsulant 80 may include a molding compound, which may include a base material and filler particles in the base material. The base material may include a polymer, a resin, and/or an epoxy. The filler particles may include silica, aluminum oxide, silicon oxide and the like. The encapsulant 80 may be formed by dispensing a molding compound in a flowable form, and curing the molding compound as a solid. Then, a planarized process such as CMP is performed on the molding compound until the diamond layer DL (e.g., diamond blocks DB) is exposed, for example. In some embodiments, the encapsulant 80 has a surface 80a and a surface 80b opposite to the surface 80a. The surface s2 of the diamond layer DL may be substantially coplanar with the surface 80b of the encapsulant 80. For example, the surfaces s2 of the diamond blocks DB are substantially coplanar with the surface 80b of the encapsulant 80. In some embodiments in which there is no additional layer between the diamond layer DL (e.g., diamond blocks DB) and the die 40 or a thickness of the additional layer may be negligible, the surface s1 of the diamond layer DL is substantially coplanar with the surface 80a of the encapsulant 80. For example, the surfaces s1 of the diamond blocks DB are substantially coplanar with the surface 80a of the encapsulant 80. In some embodiments, the surface s1 of the diamond layer DL (e.g., diamond block DB) is further substantially coplanar with the surface 62a of the encapsulant 62.

Referring to FIG. 1H, conductive connectors 82 are formed on the RDL structure 70 over the diamond layer DL. The carrier substrate C2 may be removed before forming the conductive connectors 82. In some embodiments, during the formation of the conductive connectors 82, the diamond layer DL serves as a supporting substrate, and thus another carrier substrate is omitted. In some embodiments, the removal process of the carrier substrate C2 is similar to that of the carrier substrate C1, so the detailed description thereof is omitted herein. The conductive connectors 82 may include solder bumps, and/or may include metal pillars (e.g., copper pillars), solder caps formed on metal pillars, and/or the like. In some embodiments, the conductive connectors 82 are controlled collapse chip connection (C4) bumps. For example, portions of the outermost dielectric layer 72 are removed to form a plurality of the openings, and then the conductive connectors 82 are formed in the openings to electrically connect the RDL structure 70. In some embodiments, a singulation process is performed on the reconstructed component 60 by cutting along scribe line regions (e.g., dashed lines), e.g., around the die region 12, to form packages 60′ (e.g., semiconductor devices). The singulation process may include sawing, etching, dicing, the like, or a combination thereof. For example, the singulation process includes sawing the package component 10, the encapsulant 62 encapsulating the dies 40, the encapsulant 80 encapsulating the diamond layer DL and the RDL structure 70. The singulation process singulates the die region 12 from adjacent regions to form a singulated package 60′ illustrated in FIG. 1H. The singulated package 60′ is from the die region 12. The package 60′ may include the diamond layer DL, the dies 40 over the diamond layer DL, the die 20 bonded to the dies 40, the RDL structure 70 electrically connected to the die 20 and the conductive connectors 82 electrically connected to the RDL structure 70. Each package 60′ has the diamond layer DL at a first surface 60a of the package 60', and has the conductive connectors 82 at a second surface 60b opposite to the first surface 60a, for example. In some embodiments, the surface s2 of the diamond layer DL is exposed, and the surface s1 of the diamond layer DL is thermally coupled to the dies 40.

Referring to FIG. 1I, the package 60′ is bonded to a package component 84. In some embodiments, the package component 84 is an interconnect substrate such as a package substrate, an interposer, another package or a printed circuit board. The package component 84 has conductive connectors 85. The conductive connectors 85 may include solder bumps, and/or may include metal pillars (e.g., copper pillars), solder caps formed on metal pillars, and/or the like. In some embodiments, an underfill 86 is formed around the conductive connectors 82 between the package 60′ and the package component 84. A package 90 is thus formed. The package 90 may include the package 60′ and the package component 84 electrically connected to the package 60′ through the conductive connectors 82.

The thermal conductivity of the diamond layer (e.g., diamond block or diamond substrate) is larger than the silicon substrate, and thus the diamond layer may replace the silicon substrate in 3DIC applications, to improve the heat dissipation capacity. In some embodiments, the diamond layer DL (e.g., diamond block or diamond substrate) is integrated into the package 60′ such as System-on-Integrated-Chip (SoIC). As such, heat generated during the operation of the package 60′ or 90 may be sufficiently and efficiently dissipated by the diamond layer DL. With the integration of the diamond layer DL (e.g., diamond blocks DB), the performance and the lifetime of the package 60′ or 90 may be improved.

In some embodiments, the diamond layer DL may serve as a supporting substrate to the subsequential process such as formation of the conductive connectors, and thus another carrier substrate may be omitted. However, the disclosure is not limited thereto. In alternative embodiments, another carrier substrate such as glass substrate is provided after formation of diamond layer DL.

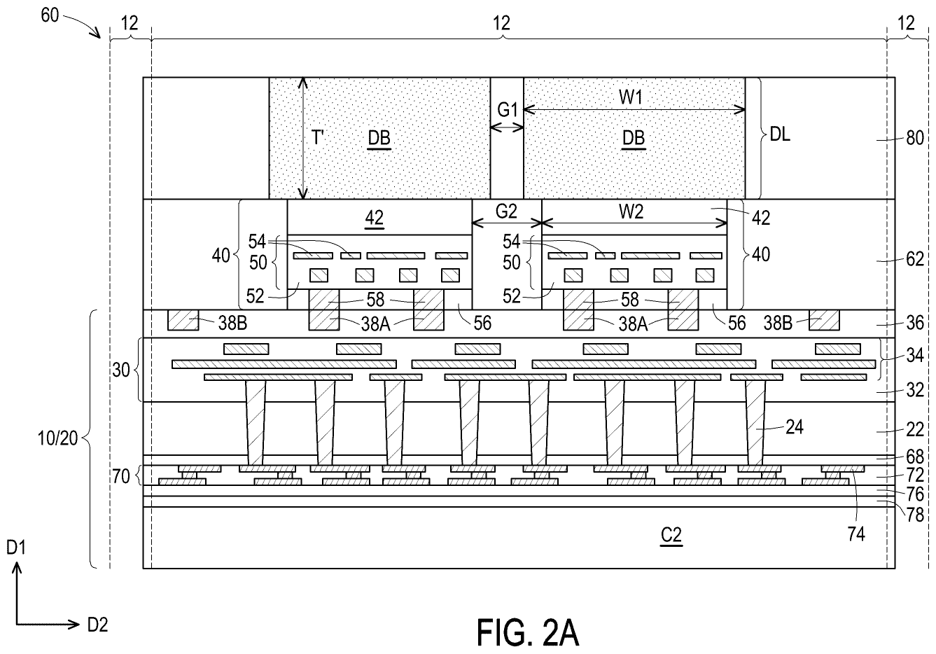

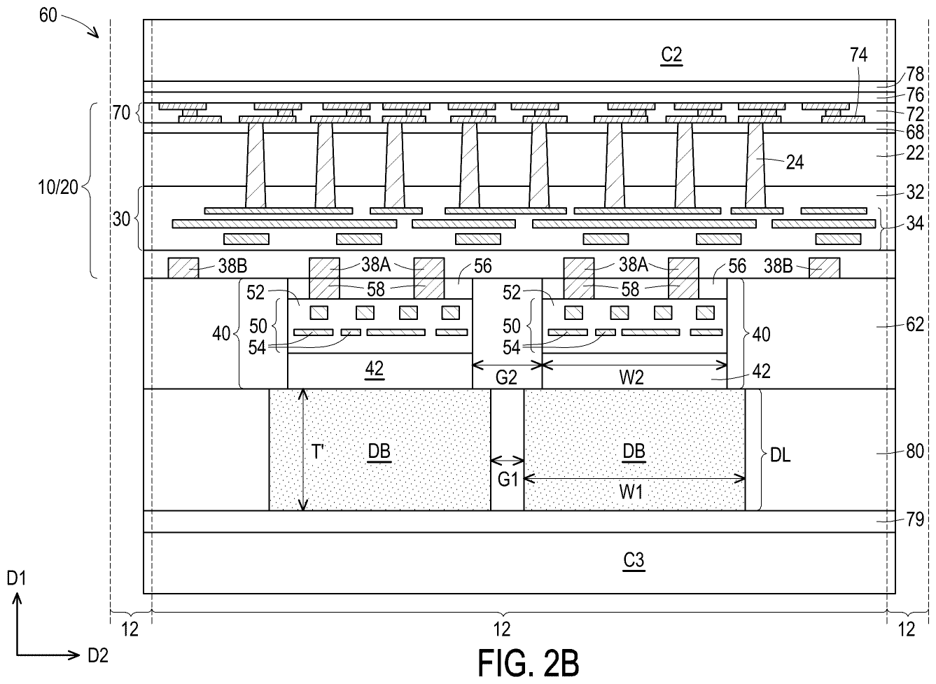

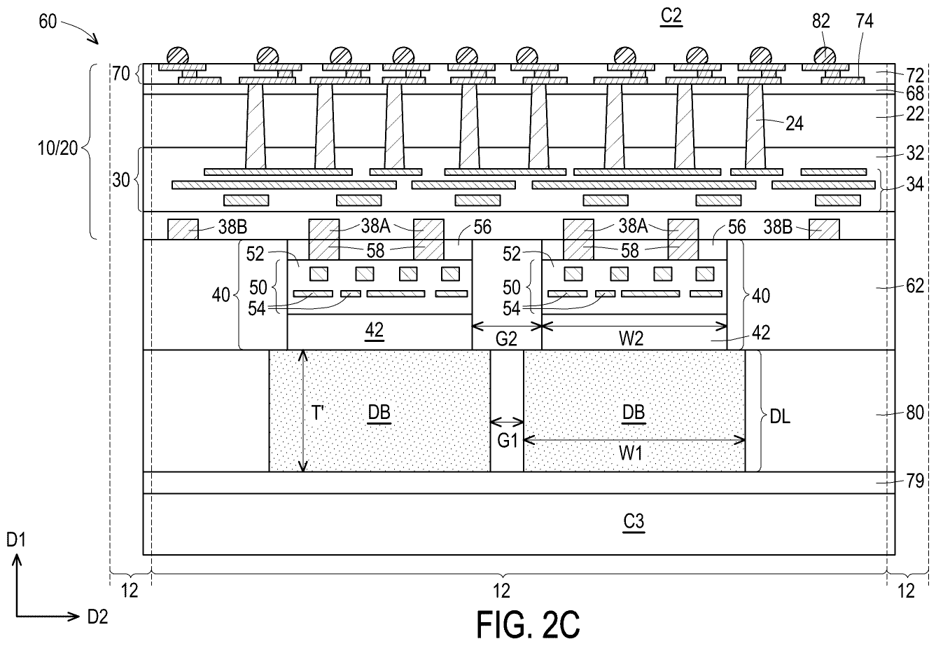

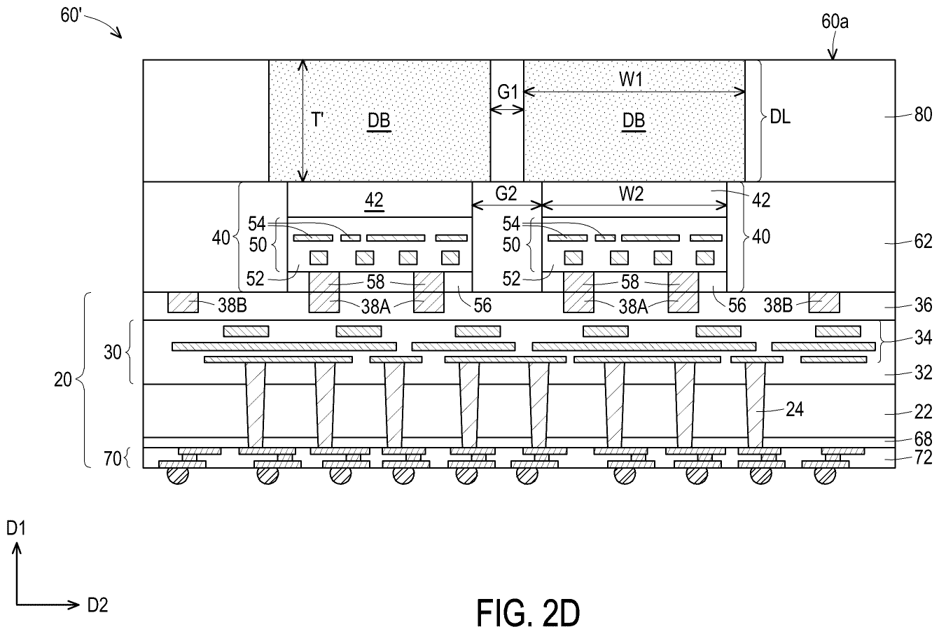

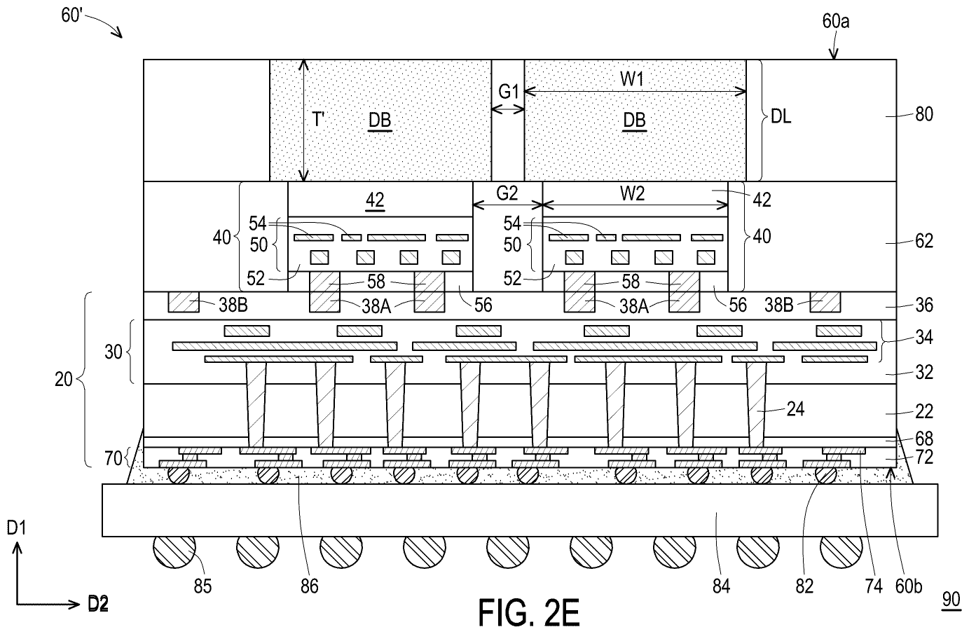

FIG. 2A to FIG. 2E are schematic cross-sectional views of various stages in a method of forming a semiconductor device according to some embodiments.

Referring to FIG. 2A, a diamond layer DL is formed over a structure of FIG. 1E, and then an encapsulant 80 is formed to encapsulate the diamond layer DL. The step of FIG. 2A is similar to the step of FIG. 1E and FIG. 1F, and the main difference lies in that the diamond layer DL has a thickness T′ smaller than the thickness T of the diamond layer DL in FIG. 1E and FIG. 1F. For example, the thickness T′ of the diamond layer DL along the direction D1 is smaller than 300μm.

Referring to FIG. 2B, the structure in FIG. 2A is turned upside down and is bonded to another carrier substrate C3 through a debond layer 79. The carrier substrate C3 and the debond layer 79 may be the same as, similar to or different from the carrier substrate C1 and the debond layer 66. In some embodiments, the carrier substrate C3 is a glass substrate while the carrier substrate C2 is a silicon substrate. The debond layer 79 includes a DAF and a LTHC release layer, for example. However, the disclosure is not limited thereto. The carrier substrate C3 and the debond layer 79 may have any other suitable materials.

Referring to FIG. 2C, the carrier substrate C2 is removed, and conductive connectors 82 are then formed on the die 20 over the carrier substrate C3. In some embodiments, the removal of the carrier substrate C2 and the formation of the conductive connectors 82 are similar to those described above, so the detailed description thereof is omitted herein. In some embodiments, during the formation of the conductive connectors 82, the carrier substrate C3 (or along with the and the diamond layer DL) serves as a supporting substrate.

Referring to FIG. 2D, the carrier substrate C3 is debonded along with the debond layer 79. In some embodiments in which the debond layer 79 includes a DAF and a LTHC release layer, the debonding process includes projecting a light such as a laser light or an UV light on the LTHC release layer, so that the LTHC release layer decomposes under the heat of the light and the carrier substrate C3 may be removed. Then, a cleaning process may be applied to remove the DAF after the carrier substrate C3 is removed. However, the disclosure is not limited thereto. The debonding process may be performed by any suitable process. Then, a singulation process may be performed to form a singulated package 60′ illustrated in FIG. 2D. In some embodiments, the singulation process is similar to those described above, so the detailed description thereof is omitted herein. In some embodiments, the package 60′ is similar to the package 60′ of FIG. 1H and the main difference lies in the thickness T′ of the diamond layer DL, so the detailed description thereof is omitted herein.

Referring to FIG. 2E, the package 60′ is bonded to a package component 84, to form a package 90. In some embodiments, the package 90 is similar to the package 90 of FIG. 1I and the main difference lies in the thickness T′ of the diamond layer DL, so the detailed description thereof is omitted herein.

In some embodiments, as shown in FIG. 1F, the carrier substrate C2 (e.g., silicon substrate) is bonded to the RDL structure 70 through the dielectric layer 64 and the debond layer 66, to provide the support during the formation of the diamond layer DL. However, the disclosure is not limited thereto. The dielectric layer 64 may be omitted based on the type of the carrier substrate C2.

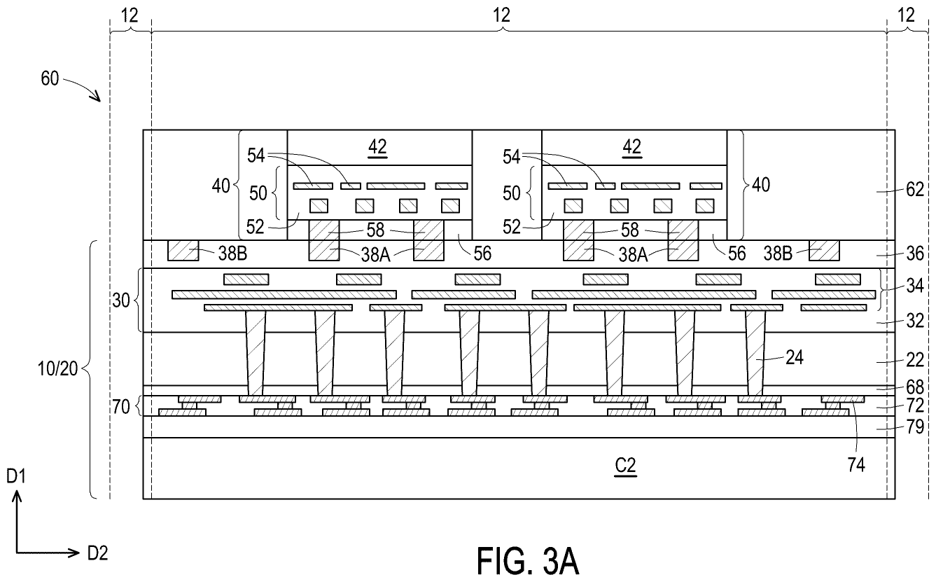

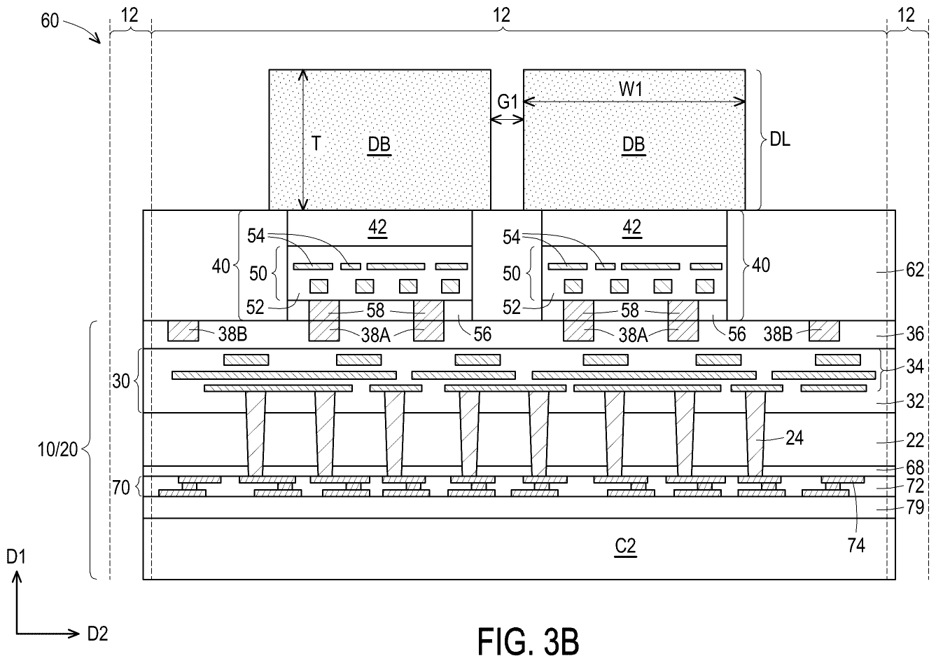

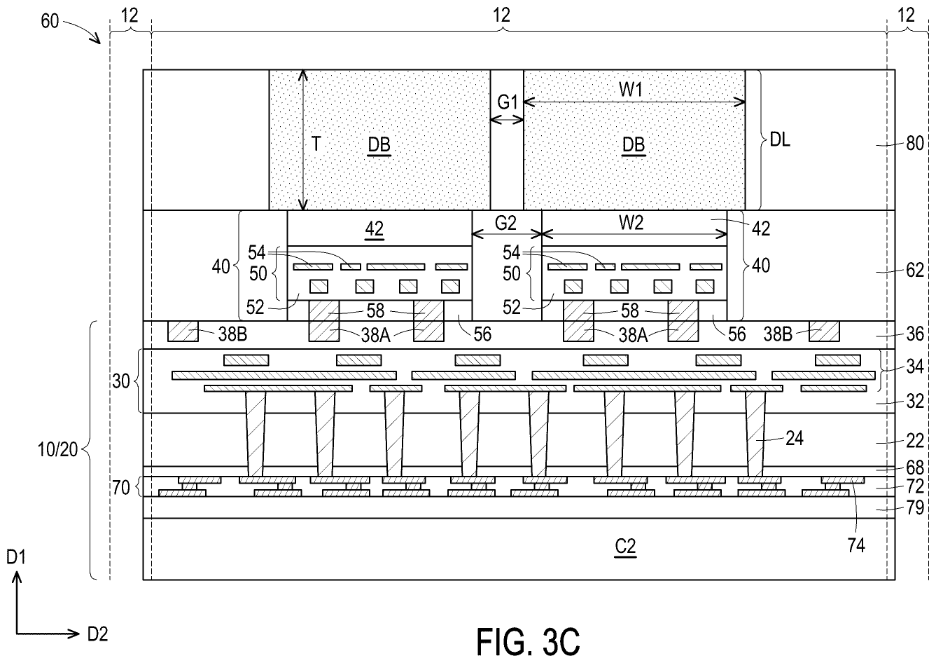

FIG. 3A to FIG. 3C are schematic cross-sectional views of various stages in a method of forming a semiconductor device according to some embodiments.

Referring to FIG. 3A, after the formation of a RDL structure 70, a carrier substrate C2 is bonded to the RDL structure 70 through a debond layer 79. In some embodiments, the structure of FIG. 3A is similar to the structure of FIG. 1E, and the main difference lies in that the carrier substrate C2 is bonded to the RDL structure 70 through the debond layer 79. In some embodiments, the carrier substrate C2 is a glass substrate, and the debond layer 79 includes a DAF and a LTHC release layer. However, the disclosure is not limited thereto. The carrier substrate C2 and the debond layer 79 may have any other suitable materials.

Referring to FIG. 3B, a diamond layer DL (e.g., diamond blocks DB) is formed on the dies 40 over the carrier substrate C2. The step of FIG. 3B may be similar to that of FIG. 1F, so the detailed description thereof is omitted herein. In some embodiments, the carrier substrate C2 may be a glass substrate, in other words, the glass substrate may be used as the carrier substrate C2 to provide the support during the formation of the diamond layer DL. However, the disclosure is not limited thereto.

Referring to FIG. 3C, an encapsulant 80 is formed to encapsulate the diamond layer DL over the carrier substrate C2 (e.g., glass substrate). The step of FIG. 3C may be similar to that of FIG. 1G, so the detailed description thereof is omitted herein. In some embodiments, the carrier substrate C2 may be a glass substrate, in other words, the glass substrate may be used as the carrier substrate C2 to provide the support during the formation of the encapsulant 80. However, the disclosure is not limited thereto.

After the formation of the encapsulant 80, the carrier substrate C2 (e.g., glass substrate) is removed along with the debond layer 79. In some embodiments in which the debond layer 79 includes a DAF and a LTHC release layer, the debonding process includes projecting a light such as a laser light or an UV light on the LTHC release layer, so that the LTHC release layer decomposes under the heat of the light and the carrier substrate C2 may be removed. Then, a cleaning process may be applied to remove the DAF after the carrier substrate C2 is removed. However, the disclosure is not limited thereto. The debonding process may be performed by any suitable process. After the carrier substrate C2 is removed, processes similar to FIG. 1H and FIG. 1I are sequentially performed, to form a package 60′ of FIG. 1H and a package 90 of FIG. 1I.

In some embodiments, during the formation of the diamond layer DL, the carrier substrate C2 serves as a supporting substrate. However, the disclosure is not limited thereto. In alternative embodiments, the die 20 (e.g., before the thinning process) may serve as a supporting substrate.

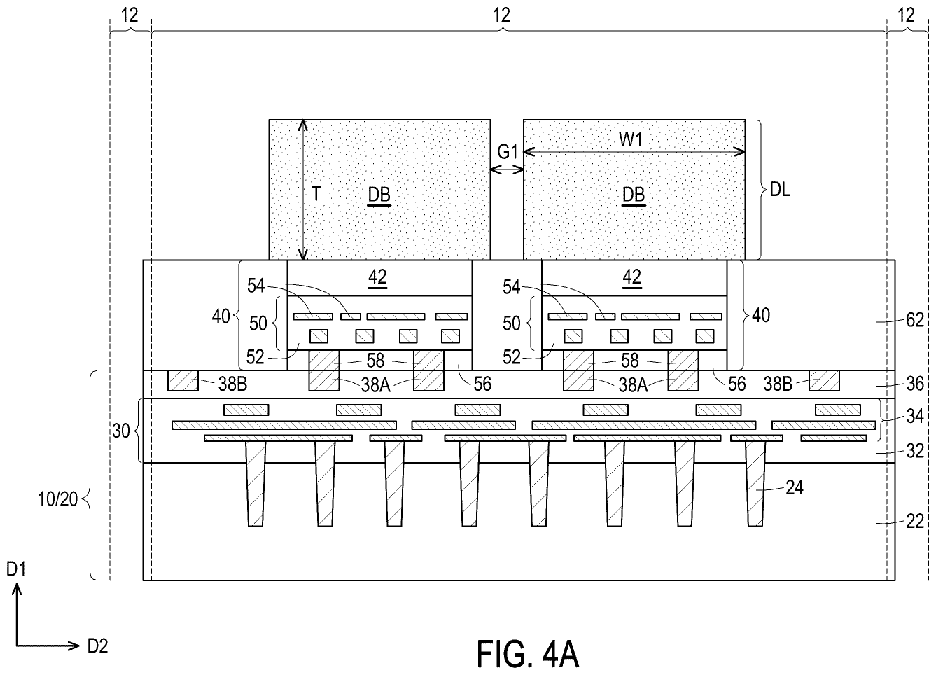

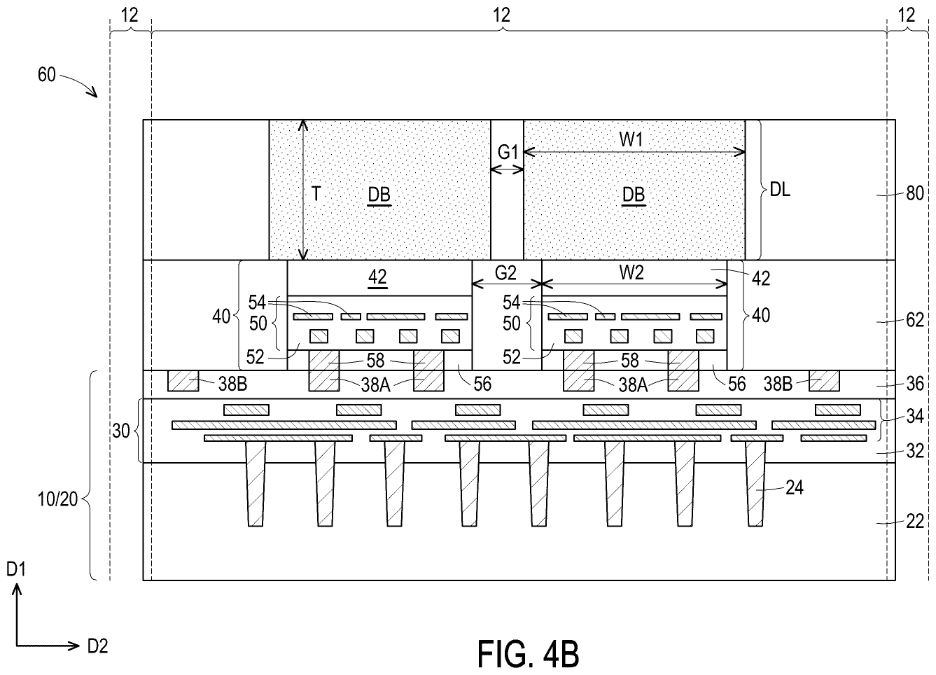

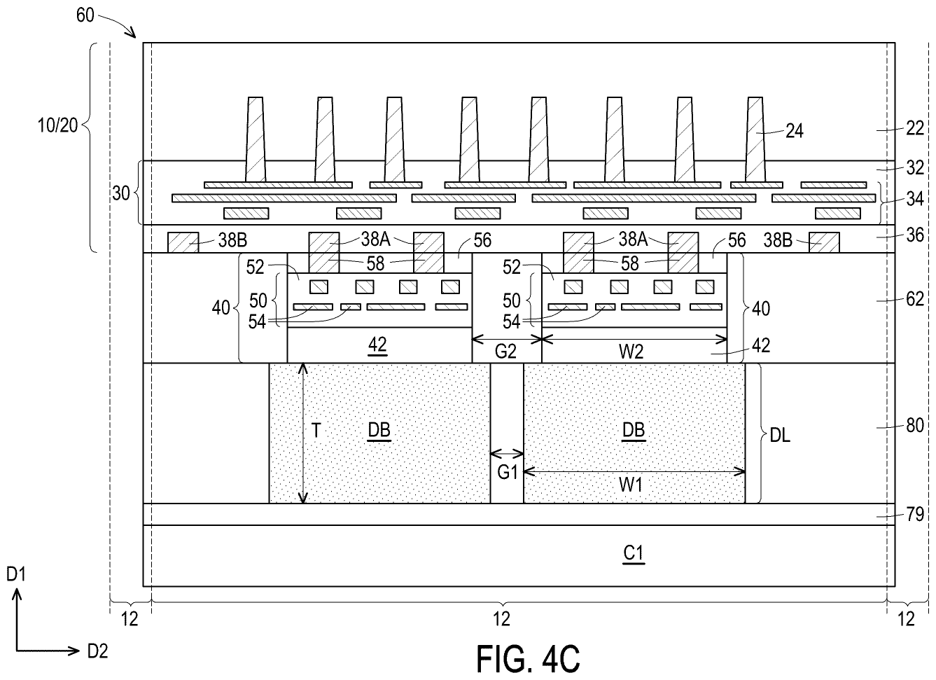

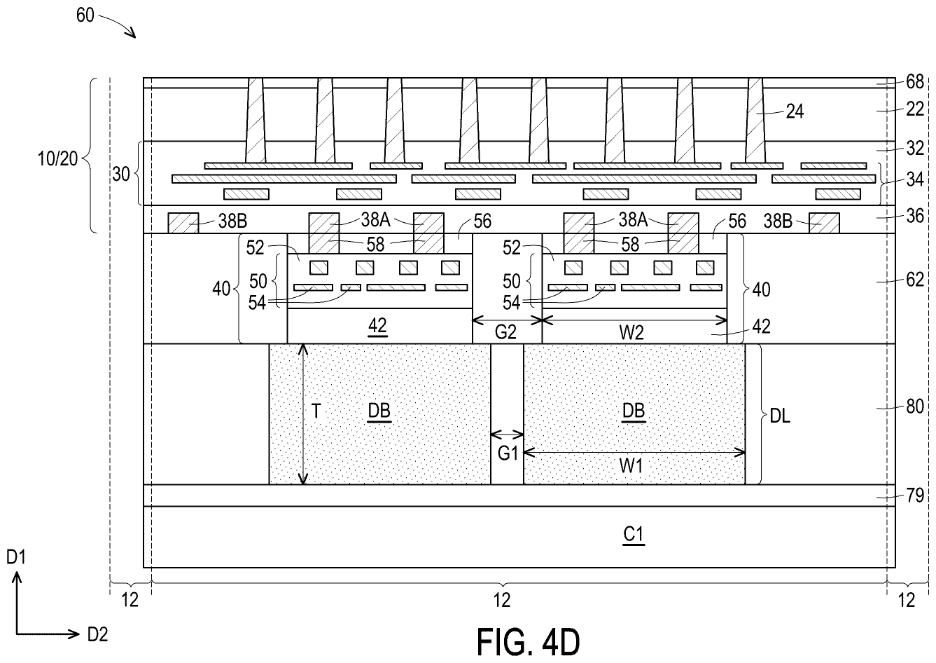

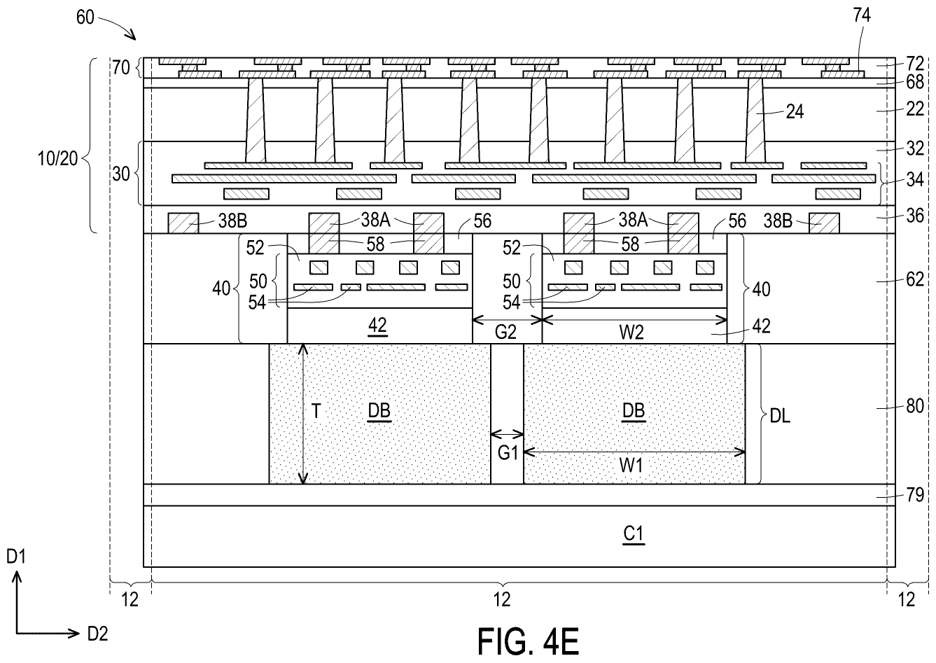

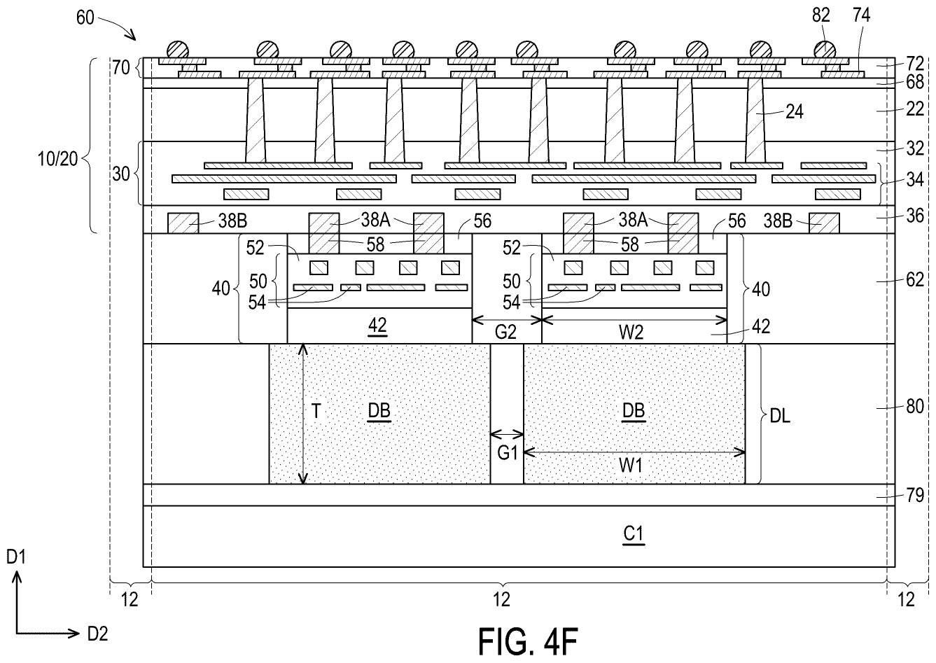

FIG. 4A to FIG. 4F are schematic cross-sectional views of various stages in a method of forming a semiconductor device according to some embodiments.

Referring to FIG. 4A, a diamond layer DL is formed on dies 40 over a die 20. In some embodiments, the die 20 (e.g., package component 10) and the dies 40 are similar to those of FIG. 1A, so the detailed description thereof is omitted herein. In some embodiments, the diamond layer DL is formed before thinning the die 20 (e.g., package component 10). Thus, the die 20 (e.g., package component 10) may be a non-thinned die (e.g., non-thinned package component 10) and have a sufficient thickness to provide support. For example, a thickness of the die 20 along a first direction D1 is in a range of 600 μm and 900μm. Thus, during the formation of the diamond layer DL, the die 20 (e.g., non-thinned die 20) may serve as a supporting substrate and a carrier substrate may be not needed. That is, the formation of the diamond layer DL is performed over the die 20 (e.g., non-thinned die 20) without a carrier substrate. In such embodiments, during the formation of the diamond layer DL, the through vias 24 are embedded in the substrate 22 of the die 20 without being exposed. However, the disclosure is not limited thereto. In alternative embodiments, the die 20 may be partially removed by an additional thinning process but still have a sufficient thickness to provide support. In such embodiments, the additional thinning process is performed before the formation of the diamond layer DL.

Referring to FIG. 4B, an encapsulant 80 is formed to encapsulate the diamond layer DL (e.g., diamond blocks DB) over the die 20. In some embodiments, the encapsulant 80 is formed over the non-thinned die 20 (e.g., non-thinned package component 10) without a carrier substrate. In some embodiments, the step of FIG. 4B is similar to the step of FIG. 1G, so the detailed description thereof is omitted herein.

Referring to FIG. 4C, the structure in FIG. 4B is turned upside down and is bonded to a carrier substrate C1 through a debond layer 79. In some embodiments, the carrier substrate C1 is a glass substrate, and the debond layer 79 includes a die attach film (DAF) and a LTHC release layer. However, the disclosure is not limited thereto. The carrier substrate C1 and the debond layer 79 may have any other suitable materials.

Referring to FIG. 4D, the die 20 is thinned over the diamond layer DL by a thinning process. After the thinning process, the through vias 24 may be exposed. In some embodiments, the step of FIG. 4D is similar to the step of FIG. 1C and the difference lies in that the thinning process is performed after the formation of the diamond layer DL, so the detailed description thereof is omitted herein. In some embodiments, the diamond layer DL may also provide mechanical strength and support along with the carrier substrate C1.

Referring to FIG. 4E, a RDL structure 70 is formed on the dies 20 and 40 over the diamond layer DL. In some embodiments, the step of FIG. 4E is similar to the step of FIG. 1D and the difference lies in that the RDL structure 70 is formed after the formation of the diamond layer DL, so the detailed description thereof is omitted herein. In some embodiments, the diamond layer DL may also provide mechanical strength and support along with the carrier substrate C1.

Referring to FIG. 4F, conductive connectors 82 are formed on the RDL structure 70 over the carrier substrate C1. In some embodiments, the formation of the conductive connectors 82 is similar to that described above and the difference lies in that the conductive connectors 82 are formed in the presence of the carrier substrate C1, so the detailed description thereof is omitted herein. In some embodiments, the diamond layer DL also provides mechanical strength and support along with the carrier substrate C1.

After formation of the conductive connectors 82, the carrier substrate C1 may be removed along with the debond layer 79. In some embodiments in which the debond layer 79 includes a DAF and a LTHC release layer, the debonding process includes projecting a light such as a laser light or an UV light on the LTHC release layer, so that the LTHC release layer decomposes under the heat of the light and the carrier substrate C1 may be removed. Then, a cleaning process may be applied to remove the DAF after the carrier substrate C1 is removed. However, the disclosure is not limited thereto. The debonding process may be performed by any suitable process. In alternative embodiments, the carrier substrate C1 is removed before the formation of the conductive connectors 82. In some embodiments, after forming the conductive connectors 82 and removing the carrier substrate C1, processes similar to FIG. 1H and FIG. 1I are performed, to form a package 60′ of FIG. 1H and a package 90 of FIG. 1I.

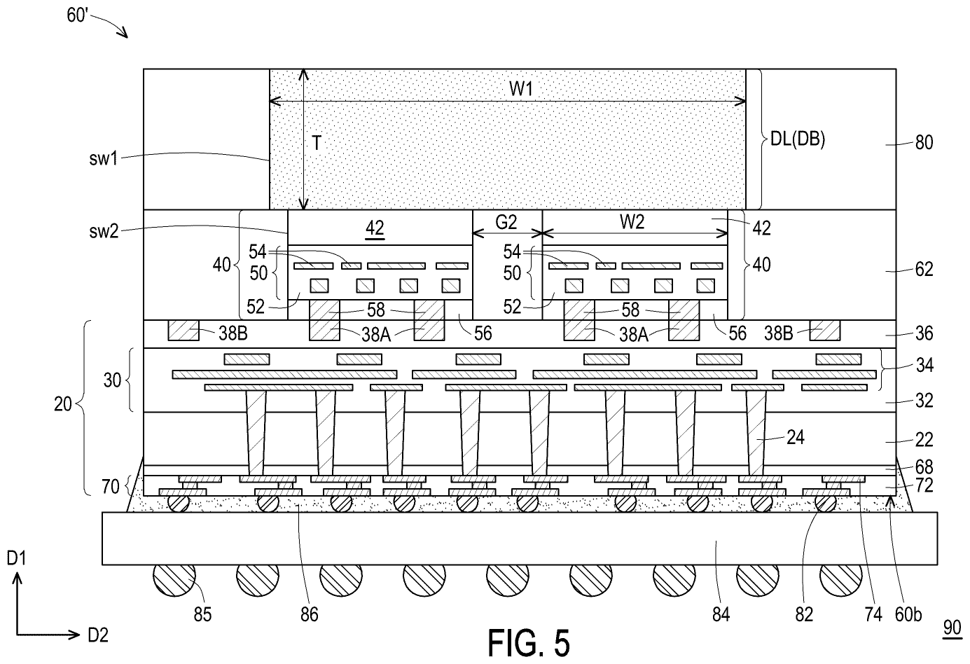

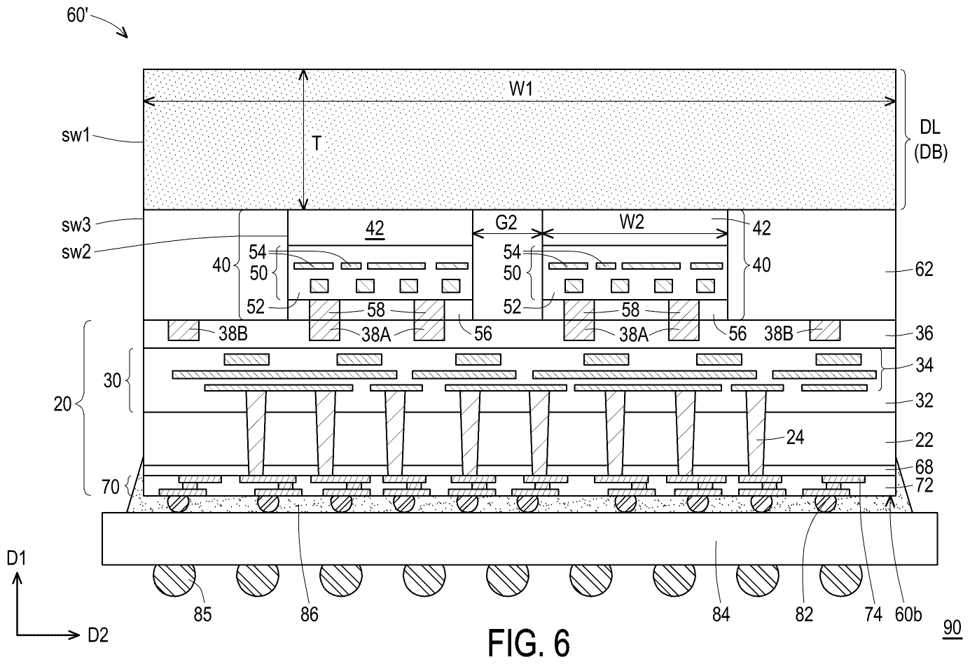

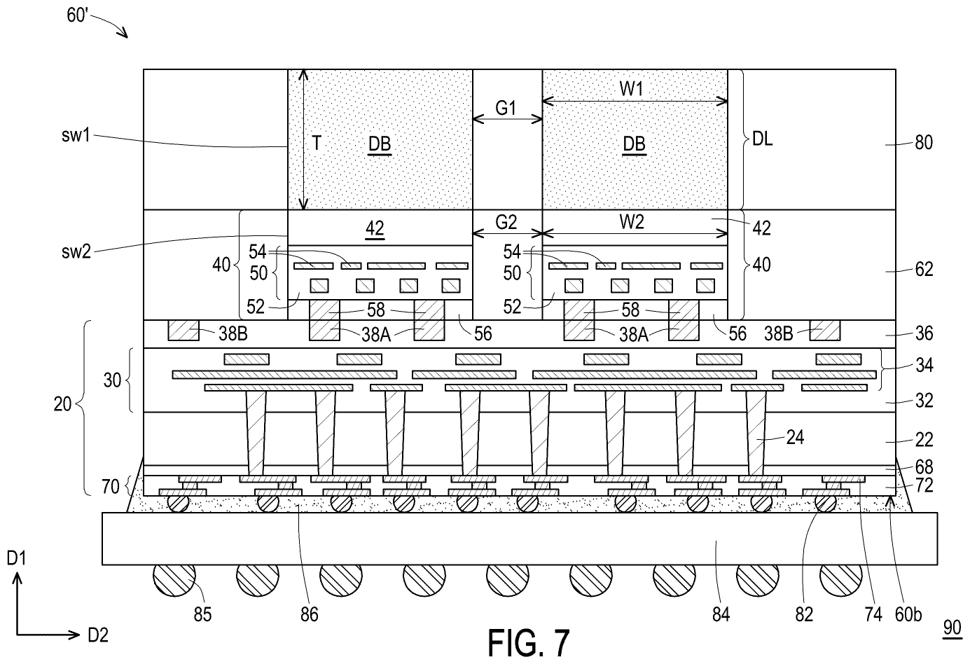

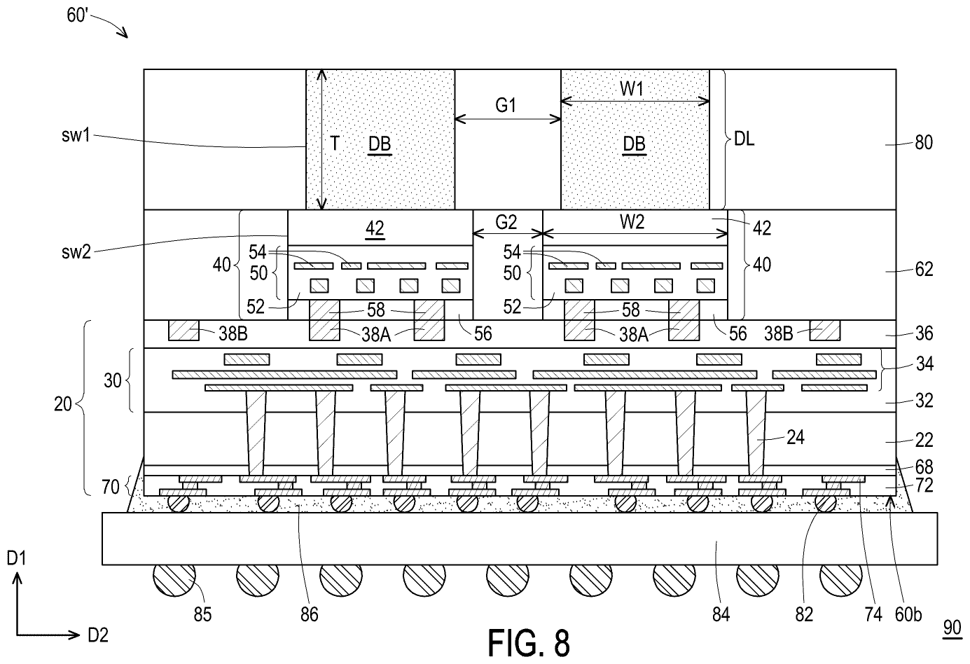

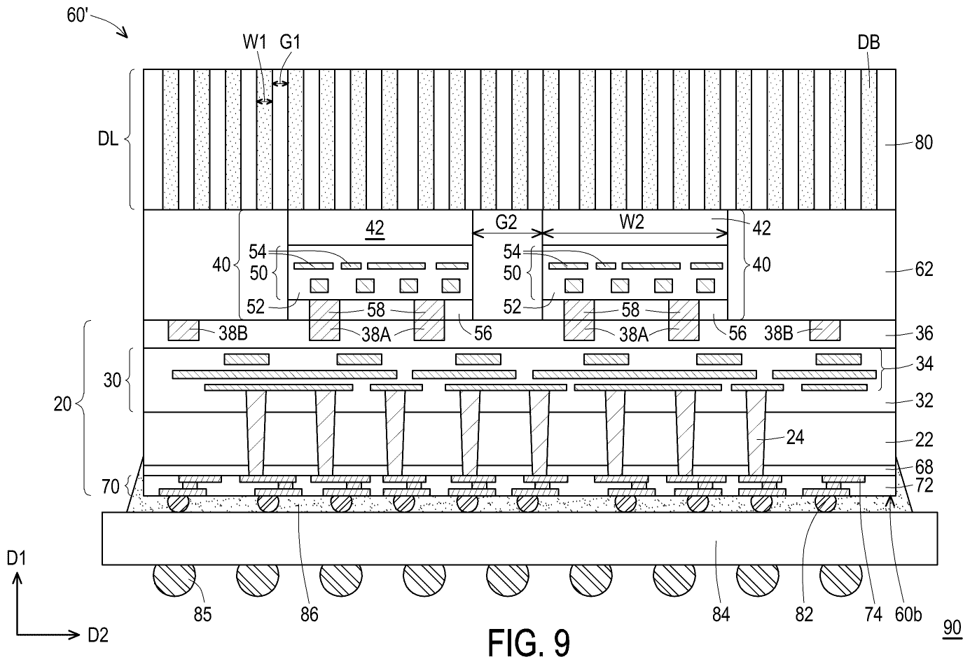

In the above embodiments, the diamond block DB of the diamond layer DL is disposed on the die 40 respectively. That is, one diamond block DB may be disposed on one die 40. However, the disclosure is not limited thereto. In some embodiments, as shown in FIG. 5, the diamond block DB is disposed over two or more dies 40. In such embodiments, the diamond block DB continuously cover two or more the dies 40. For example, a width W1 of the diamond block DB is substantially equal to or larger than a total width of the dies 40 (e.g., 2*W2) and the gap (e.g., G2) therebetween. For example, opposing sidewalls sw1 of the diamond block DB are disposed outside the outermost sidewalls sw2 of the dies 40. In some embodiments, as shown in FIG. 6, the diamond block DB has a sidewall sw1 substantially flush with a sidewall sw3 of the encapsulant 62. For example, the opposite sidewalls sw1 of the diamond block DB are disposed outside the outermost sidewalls sw2 of the dies 40, and the opposite sidewalls sw1 of the diamond block DB are substantially flush with the opposing sidewalls sw3 of the encapsulant 62. In such embodiments, the encapsulant 80 encapsulating the diamond block DB may be omitted. In some embodiments, as shown in FIG. 7, the width W1 of the diamond block DB is substantially equal to the width W2 of the die 40, and the opposing sidewalls sw1 of the diamond block DB are substantially flush with the opposing sidewalls sw2 of the die 40. In some embodiments, as shown in FIG. 8, the width W1 of the diamond block DB is smaller than the width W2 of the die 40, a portion of the die 40 is exposed by the diamond block DB. For example, the portion of the die 40 is covered by the encapsulant 80. In some embodiments, as shown in FIG. 9, the width W1 of the diamond block DB is smaller than the width W2 of the die 40, and the diamond blocks DB are pillar-shaped. In such embodiments, more than one diamond blocks DB is disposed over one die 40. The diamond blocks DB may include substantially identical width W1 or different widths W1. The diamond blocks DB may be uniformly arranged or randomly arranged, and the gaps G1 between the diamond blocks DB may be substantially identical or different. As shown in FIG. 9, each of the diamond blocks DB is entirely or partially overlapped with the device die 40 or is not overlapped with the device die 40 but overlapped with the encapsulant 62. In alternative embodiments, the diamond blocks DB are overlapped with the device dies 40 and not overlapped with the encapsulant 62.

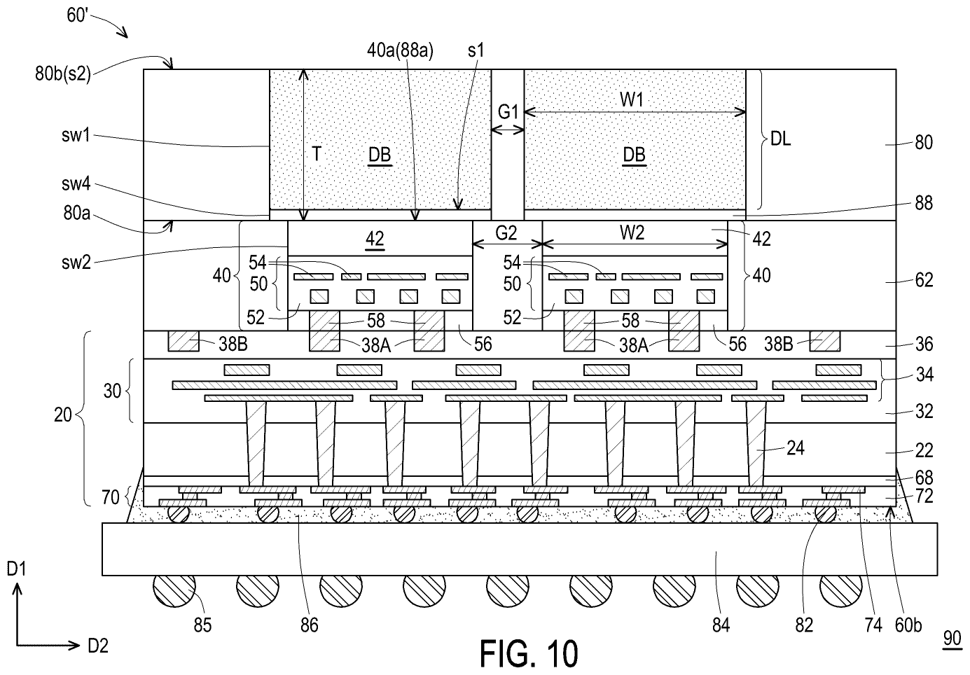

In some embodiments, as shown in FIG. 10, a bonding layer 88 is further disposed between the diamond layer DL and the die 40. For example, the bonding layer 88 is further disposed between the diamond block DB and the die 40. The bonding layer 88 may provide adhesion between the diamond layer DL and the die 40 (e.g., substrate 42). In such embodiments, the treatment to the diamond layer DL and the substrate 42 of the die 40 may be omitted. In some embodiments, a material of the bonding layer 88 include silicon oxide, metal oxide such as aluminum oxide, metal nitride such as aluminum nitride or the like. However, the disclosure is not limited thereto. In alternative embodiments, other materials having adhesion properties may also be applicable as materials for the bonding layer 88. In some embodiments, the bonding layer 88 is formed by suitable fabrication techniques, such as ALD, CVD, PECVD, spin-on coating or the like. In some embodiments, the bonding layer 88 is formed on the diamond layer DL and/or the die 40 before disposing the diamond layer DL onto the die 40. For example, the bonding layer 88 is formed on the diamond layer DL (e.g., diamond block DB), a planarization process is performed on the bonding layer 88 to reduce a surface roughness thereof. In some embodiments, a thickness of the bonding layer 88 along the direction D1 is 30 nm or less. For example, the thickness of the bonding layer 88 along the direction D1 is in a range of about 1 nm and about 30 nm. In some embodiments, the diamond block DB has a sidewall sw1 substantially flush with a sidewall sw4 of the bonding layer 88. For example, the opposite sidewalls sw1 of the diamond block DB are substantially flush with the opposing sidewalls sw4 of the bonding layer 88. The bonding layer 88 may directly contact the substrate 42 of the die 40 and the diamond layer DL. For example, a surface 88a of the bonding layer 88 is substantially coplanar with a surface 40a of the die 40 and a surface 80a of the encapsulant 80. A surface 80b opposite to the surface 80a of the encapsulant 80 may be substantially coplanar with a surface s2 of the diamond layer DL, while a surface s1 opposite to the surface s2 of the diamond layer DL may be disposed between the surface 40a of the die 40 and the surface 80b of the encapsulant 80.

In the above embodiments, the diamond layer DL is formed on the dies 40 by placing the diamond block DB onto the dies 40. However, the disclosure is not limited thereto. The diamond layer DL may be directly formed on the dies 40 over the die 20 (e.g., package component 10) by a deposition process, a coating process or the like.

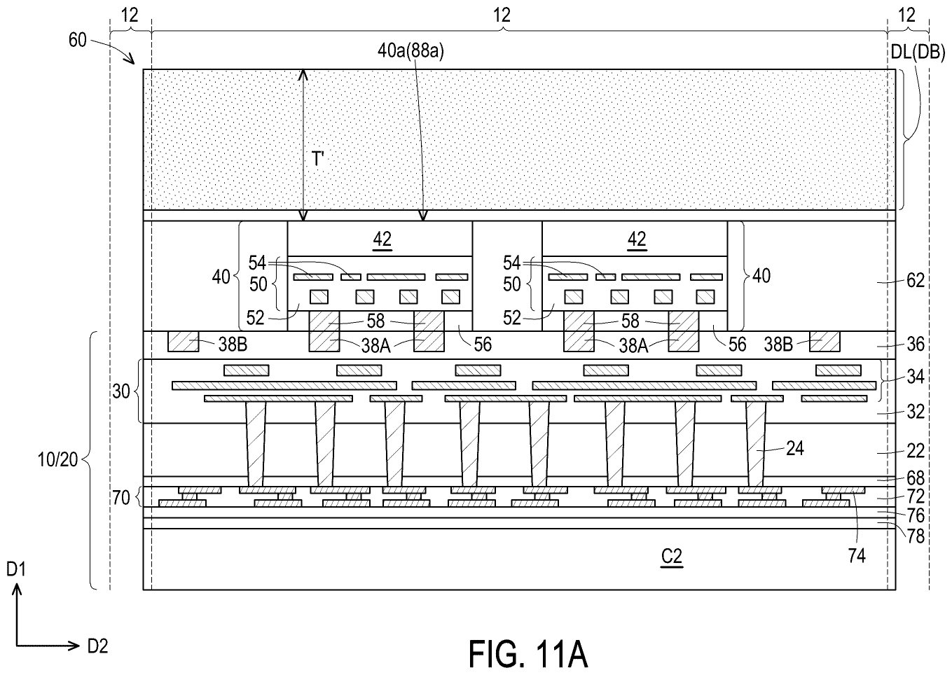

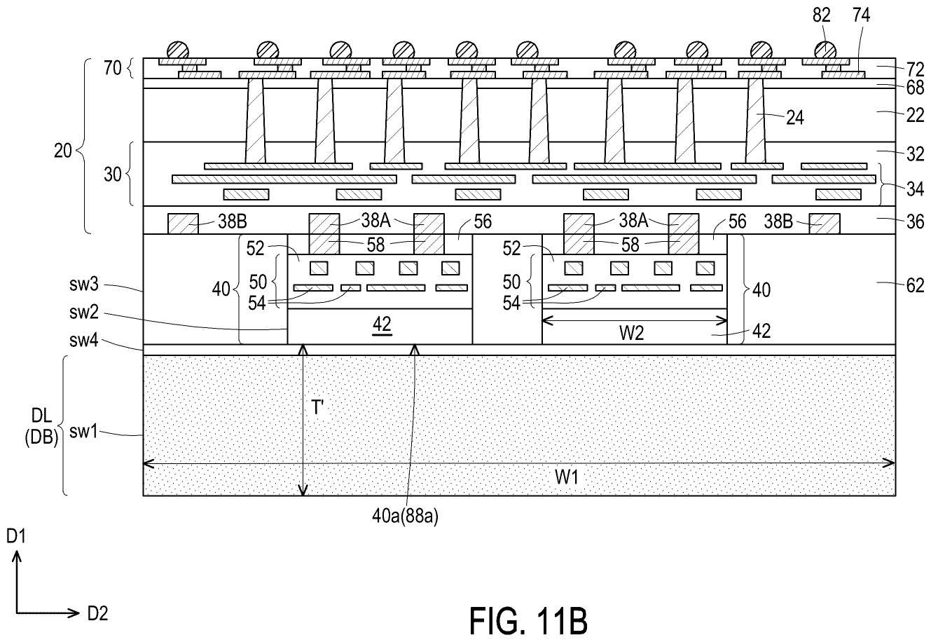

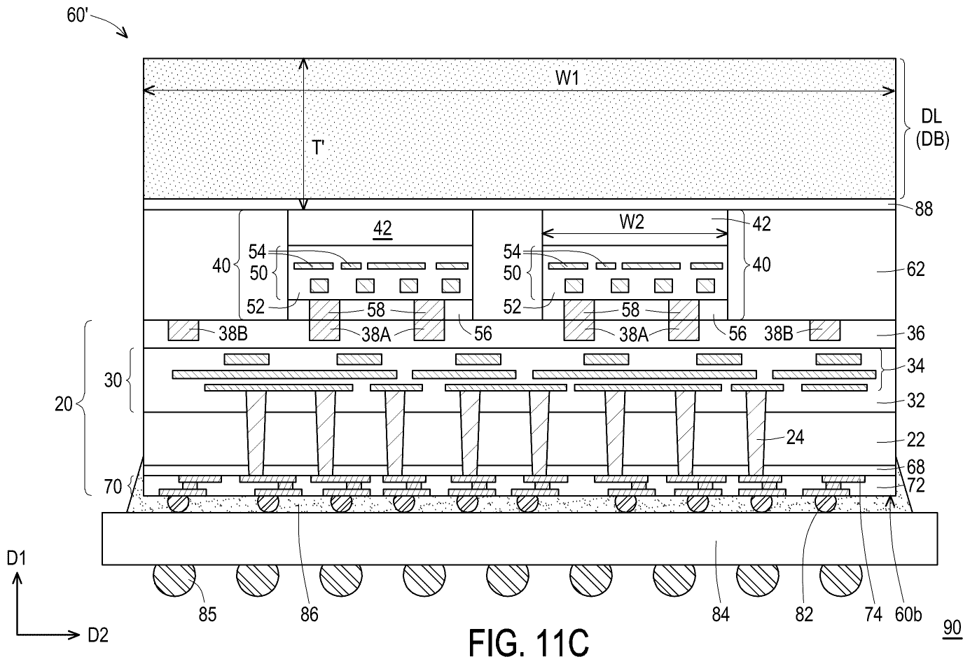

FIG. 11A to FIG. 11C are schematic cross-sectional views of various stages in a method of forming a semiconductor device according to some embodiments.

Referring to FIG. 11A, a structure of FIG. 1E is provided, and a diamond layer DL is formed over dies 40. Diamond as used herein may refer to diamond or diamond like carbon (DLC) coating. The diamond layer DL may be formed over the dies 40 and the encapsulant 62 by using a depositing process such as CVD, atomic layer deposition (ALD), plasma enhanced chemical vapor deposition (PECVD), physical vapor deposition (PVD), a coating process such as spin-on coating, or the like. In an embodiment in which the diamond-based dielectric material is deposited using CVD, a carbon-containing gas and hydrogen (H₂) may be used. The carbon-containing gas may include methane, dichloromethane, trichloromethane, or a combination thereof. In an embodiment in which the diamond-based dielectric material is deposited using spin-on coating, a dispersed diamond precursor solution may be used. To improve quality of the diamond layer DL, an anneal process may be performed after their deposition. A thickness T of the diamond layer DL along the direction D1 is in a range of 300μm to 1000μm, for example. In some embodiments, the diamond layer DL continuously extends over the dies 40 and the encapsulant 62. In alternative embodiments (not shown), the diamond layer DL may be formed on a carrier and then transferred onto the dies 40.

In some embodiments, before forming the diamond layer DL, a bonding layer 88 is optionally formed over the substrates 42 of the dies 40 and the encapsulant 62. The bonding layer 88 may provide adhesion between the diamond layer DL and the die 40. The bonding layer 88 may directly contact the substrate 42 of the die 40 and the diamond layer DL. For example, a surface 88a of the bonding layer 88 is substantially coplanar with a surface 40a of the die 40. In some embodiments, a material of the bonding layer 88 include silicon oxide, metal oxide such as aluminum oxide, metal nitride such as aluminum nitride or the like. However, the disclosure is not limited thereto. In alternative embodiments, other materials having adhesion properties may also be applicable as materials for the bonding layer 88. In some embodiments, the bonding layer 88 is formed by suitable fabrication techniques, such as ALD, CVD, PECVD, spin-on coating or the like. In some embodiments, a thickness of the bonding layer 88 along the direction D1 is 30 nm or less. For example, the thickness of the bonding layer 88 along the direction D1 is in a range of about 1 nm and about 30 nm.

In alternative embodiments (not shown), a patterning process is performed to the diamond layer DL and/or the bonding layer 88, so that the diamond layer DL and/or the bonding layer 88 is patterned to have a suitable shape and/size. For example, the diamond layer DL is patterned to form a plurality of diamond block(s) DB as shown in FIG. 1F and FIG. 5 to FIG. 9, and then an encapsulant 80 is formed to encapsulate the diamond block(s) DB. In alternative embodiments, a patterning process is performed to both the diamond layer DL and the bonding layer 88, and then an encapsulant 80 is formed to encapsulate the diamond block(s) DB and the bonding layer 88, to form a structure of FIG. 10.

Referring to FIG. 11B, conductive connectors 82 are formed on the RDL structure 70 over the diamond layer DL. In some embodiments, the step of FIG. 11B is similar to the step of FIG. 1H, so the detailed description thereof is omitted herein. In some embodiments, the reconstructed component 60 may then be sawed to form packages 60′. For example, the package component 10, the encapsulant 62 encapsulating the dies 40, the diamond layer DL and the RDL structure are sawed. In some embodiments, the width W1 is larger than a total width (e.g., 2*W2) of the dies 40, for example. In some embodiments, the diamond layer DL has a sidewall sw1 extends beyond a sidewall sw2 of the die 40, and the sidewall sw1 of the diamond layer DL is substantially flush with a sidewall sw4 of the bonding layer 88 and a sidewall sw3 of the encapsulant 62. For example, the opposite sidewalls sw1 of the diamond layer DL are substantially flush with the opposing sidewalls sw4 of the bonding layer 88 and the opposing sidewalls sw3 of the encapsulant 62.

Referring to FIG. 11C, the package 60′ is bonded to a package component 84, to form a package 90. In some embodiments, the package component 84 is similar to the package component 84 of FIG. 1I, so the detailed description thereof is omitted herein.

In the above embodiments, the diamond layer is integrated into a package such as SoIC. However, the disclosure is not limited thereto. The diamond layer may be integrated into any suitable 3DIC structure.

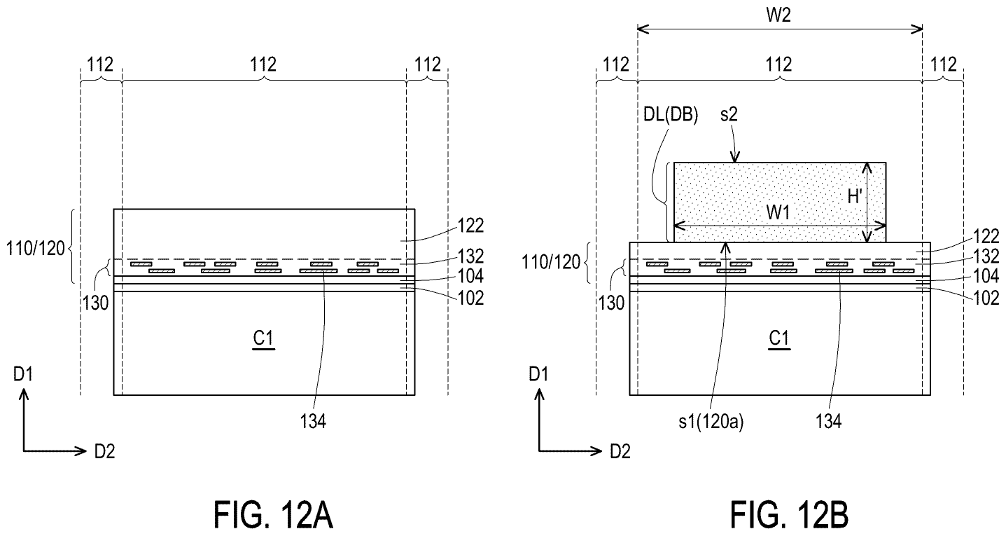

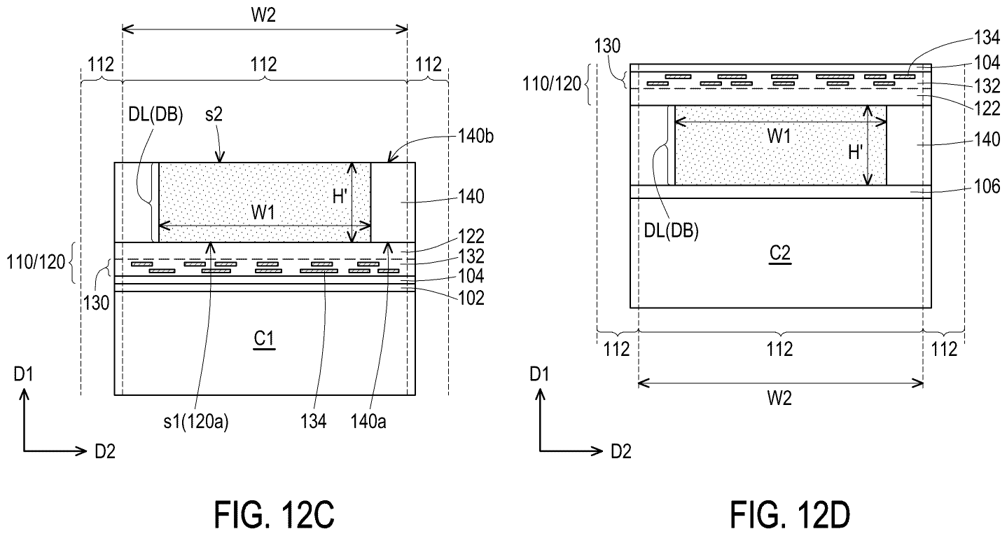

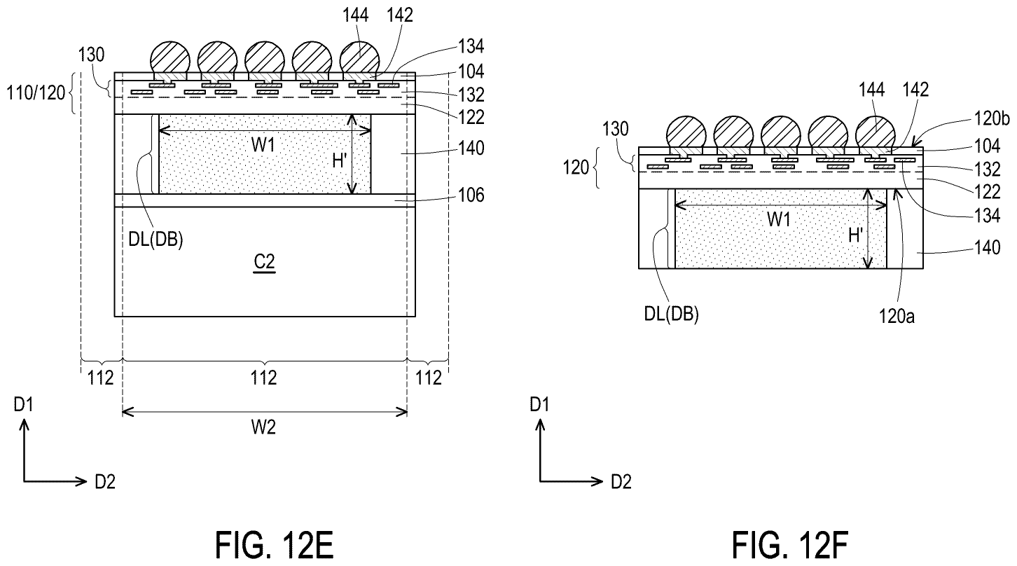

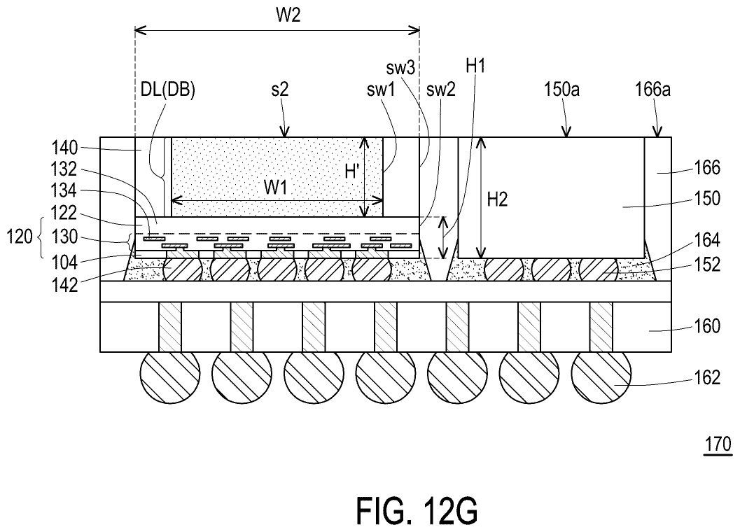

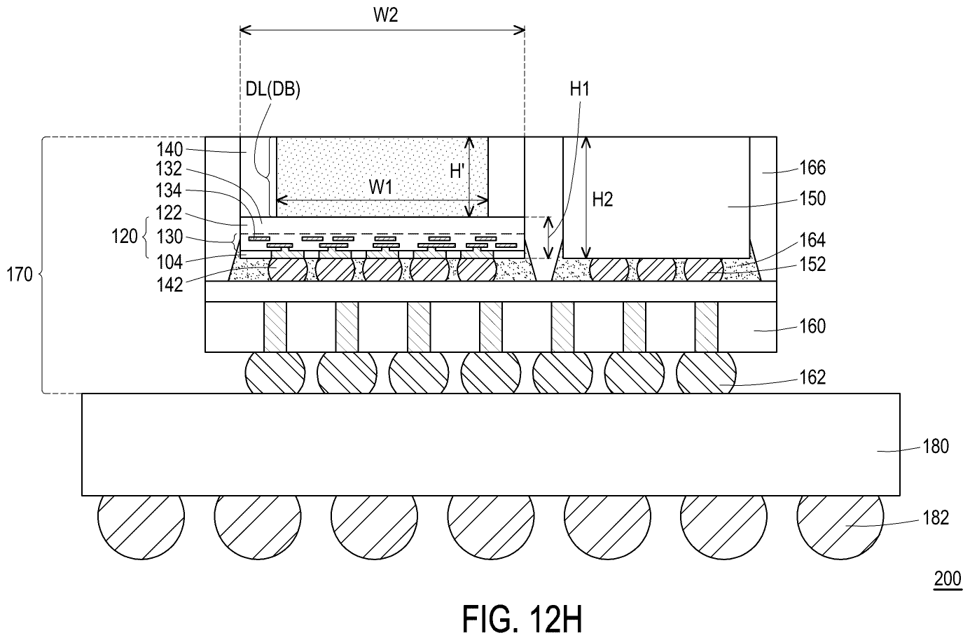

FIG. 12A to FIG. 12H are schematic cross-sectional views of various stages in a method of forming a semiconductor device according to some embodiments.

Referring to FIG. 12A, a package component 110 is bonded to a carrier substrate C1 along a direction D1. The direction D1 is a vertical direction (e.g., z direction), and a direction D2 substantially perpendicular to the direction D1 is a horizontal direction (e.g., x direction or y direction), for example. In some embodiments, a debond layer 102 and a dielectric layer 104 are stacked over the carrier substrate C1 in sequential order. The carrier substrate C1 and the debond layer 102 are similar to the carrier substrate C1 and the debond layer 66 described above, so the detailed description thereof is omitted herein. In some embodiments, the dielectric layer 104 includes polymer such as polyimide, benzocyclobutene (BCB), polybenzoxazole (PBO), or the like. In alternative embodiments, the dielectric layer 104 includes non-organic dielectric materials such as silicon oxide, silicon nitride, silicon carbide, silicon oxynitride, or the like.

The package component 110 may include a plurality of die regions 112 that are singulated in subsequent steps to form a plurality of dies 120. For example, the die regions 112 are separated by scribe line regions (not shown) therebetween. The die 120 may be a logic die (e.g., central processing unit (CPU), graphics processing unit (GPU), system-on-chips (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or a combination thereof. A thickness of the die 120 along the direction D1 is in a range of 300μm and 500μm, for example. The die 120 may include a substrate 122 and an interconnect structure 130. In some embodiments, the substrate 122 and the interconnect structure 130 are similar to the substrate 22 and the interconnect structure 30, so the detailed description thereof is omitted herein. For example, the interconnect structure 130 includes one or more dielectric layer(s) 132 and conductive features 134 in the dielectric layer(s) 132. The die 120 may have any suitable structure. For example, the die 120 has a structure similar to the die 20 or 40 as described above or the like. In some embodiments, a surface of the package component 110 to be bonded to the carrier substrate C1 is planarized using a CMP process or a mechanical grinding process before bonding to the carrier substrate C1.

Referring to FIG. 12B, after bonding to the carrier substrate C1, the substrate 122 of the package component 110 is thinned. In some embodiments, the substrate 122 is partially removed by a thinning process such as a CMP process or a mechanical grinding process. After performing the thinning process, the thickness of the package component 110 along the direction D1 is in a range of 50μm and 100μm, for example.

Then, a diamond layer DL (e.g., diamond block DB) is disposed over the package component 110. The diamond layer DL may be formed on a surface 120a of the die 120 by a pick-and-place process. A surface s1 of the diamond layer DL is in direct contact with the surface 120a of the die 120 (e.g., substrate 122) to be bonded, for example. In some embodiments, the forming method of the diamond layer DL is similar to that of the diamond layer DL described with reference to FIG. 1F, so the detailed description thereof is omitted herein. In some embodiments, the diamond layer DL includes a single diamond block DB (e.g., diamond substrate) and has a width W1 along the direction D2 smaller than a width W2 of the die 120 to be formed. A plasma treatment is performed on a surface of the diamond layer DL to be bonded to the die 120, for example. However, the disclosure is not limited thereto. The diamond layer DL may have any suitable configuration as shown in FIG. 1I and FIG. 5 to FIG. 10 or the like, and the diamond layer DL and/or the die 120 may be treated by a treatment process before bonding as described above.

In some embodiments, a height (e.g., thickness) H′ of the diamond layer DL is substantially equal to a height difference between the die 120 and a die 150 to be packaged with the die 120 (e.g., a height difference between a height H1 of the die 120 and a height H2 of the die 150 in FIG. 12G). The height (e.g., thickness) H′ of the diamond layer DL may be measured from the surface s1 to the surface s2 opposite to the surface s1. The height (e.g., thickness) H′ of the diamond layer DL may be in a range of about 300μm to 500μm, for example.

Referring to FIG. 12C, an encapsulant 140 is formed to encapsulate the diamond layer DL. In some embodiments, the encapsulant 140 is similar to the encapsulant 80, so the detailed description thereof is omitted herein. For example, a material of the encapsulant 140 is formed to cover the diamond layer DL and then a planarized process such as CMP is performed on the material of the encapsulant 140 until the surface s2 of the diamond layer DL is exposed. The encapsulant 140 has a surface 140a and a surface 140b opposite to the surface 140a. In some embodiments, the surface s2 of the diamond layer DL is substantially coplanar with the surface 140b of the encapsulant 140. In an embodiment in which there is no additional layer between the diamond layer DL and the die 120 or a thickness of the additional layer may be negligible, the surface s1 of the diamond layer DL is substantially coplanar with the surface 140a of the encapsulant 140 and the surface 120a of the die 120 (e.g., substrate 122).

Referring to FIG. 12D, the structure of FIG. 12C is bonded to a carrier substrate C2 through a debond layer 106, and then the carrier substrate C1 is removed. The carrier substrate C2 and the debond layer 106 may have any other suitable materials described above. In some embodiments, the carrier substrate C2 is a glass substrate, and the debond layer 106 includes a DAF and a LTHC release layer. The removal process of the carrier substrate C1 are similar to those described with reference to FIG. 1E, so the detailed description thereof is omitted herein.

Referring to FIG. 12E, conductive connectors 144 are formed to electrically connect the interconnect structure 130 over the diamond layer DL. For example, a plurality of openings are formed in the dielectric layer 104 (and optionally the dielectric layer 132) to expose portions of the metal features 134 of the interconnect structure 130. Then, conductive patterns 142 may be formed in the openings to electrically connect to the metal features 134 of the interconnect structure 130. The conductive patterns 142 may be conductive pad, conductive via, the like or a combination thereof. After that, the conductive connectors 144 are formed on the dielectric layer 104 to electrically connect the interconnect structure 130 through the conductive patterns 142. The conductive connectors 144 provide an external electrical connection to the circuitry and devices. The conductive connectors 144 may include solder bumps, and/or may include metal pillars (e.g., copper pillars), solder caps formed on metal pillars, and/or the like.

Referring to FIG. 12F, the structure of FIG. 12E is debonded from the carrier substrate C2. The structure of FIG. 12E may be debonded from the carrier substrate C2 and then mounted onto a frame (not shown). In some embodiments, a singulation process is performed on the wafer-level structure by cutting along scribe line regions (e.g., dashed lines), e.g., around the die region 112. The singulation process may include sawing, etching, dicing, the like, or a combination thereof. For example, the singulation process includes sawing the encapsulant 140, the substrate 122, the interconnect structure 130 and the dielectric layer 104. The singulation process singulates the die region 122 from adjacent regions to form a singulated die 120 illustrated in FIG. 12F. The singulated die 120 is from the die region 112. Each die 120 may include the diamond layer DL on the surface 120a of the die 120 (e.g., substrate 122). In some embodiments, the conductive connectors 144 are disposed at a surface 120b opposite to the surface 120a of the die 120. In some embodiments, the surface s2 of the diamond layer DL is exposed, and the surface s1 of the diamond layer DL is thermally coupled to the die 120. For example, the diamond layer DL is continuously disposed on and in direct contact with the surface 120a of the die 120.

Referring to FIG. 12G, the die 120 and a die 150 are bonded to a package component 160, and a package 170 is thus formed. In some embodiments, the die 120 includes the diamond layer DL, and a sidewall sw1 of the diamond layer DL is inside a sidewall sw2 of the die 120. The sidewall sw2 of the die 120 is substantially flush with a sidewall sw3 of the encapsulant 140, for example. The die 150 is the same as or different from the die 120. The die 150 may be a memory device that includes multiple memory dies such as a hybrid memory cube (HMC) device, a high bandwidth memory (HBM) device, or the like. The die 150 includes conductive connectors 152 on the outermost surface. The conductive connectors 152 may be formed using similar materials and methods as the conductive connectors 144 described above with reference to FIG. 12E, so the detailed description thereof is omitted herein. In some embodiments, the die 150 also includes a diamond layer therein, to improve the heat dissipation efficiency.

The package component 160 may be an interconnect substrate such as a package substrate, an interposer, another package, a printed circuit board, or the like. The package component 160 includes conductive connectors 162. The conductive connectors 162 may include solder bumps, and/or may include metal pillars (e.g., copper pillars), solder caps formed on metal pillars, and/or the like. In some embodiments, an underfill 164 is formed around the conductive connectors 144 and 152 between the dies 120, 150 and the package component 160. Then, an encapsulant 166 is formed around the dies 120, 150 on the package component 160. After formation, the encapsulant 166 encapsulates the dies 120, 150 and the underfill 164. In some embodiments, the encapsulant 166 encapsulates the dies 120, 150 and the diamond layer DL on the die 120 and fills the gaps between the dies 120, 150. The encapsulant 166 may include a molding compound, which may include a base material and filler particles in the base material. The base material may include a polymer, a resin, and/or an epoxy. The filler particles may include silica, aluminum oxide, silicon oxide and the like. The encapsulant 166 may be formed by dispensing a molding compound in a flowable form, and curing the molding compound as a solid. Then, a planarized process such as CMP is performed on the molding compound until the diamond layer DL (e.g., surface s2) and the die 150 (e.g., surface 150a) are exposed, for example.

In some embodiments, the die 150 has a thickness H2 larger than a thickness H1 of the die 120, in other words, a thickness difference is between the die 120 and the die 150. In some embodiments, a total height (e.g., H1 plus H′) of the die 120 and the diamond layer DL thereon is substantially equal to a height H2 of the die 150. The height H2 is in a range of about 0.7 mm and about 1.1 mm, for example. In other words, the diamond layer DL may compensate the height difference between the die 120 and the die 150 to be packaged. Thus, the surface s2 (e.g., top surface) of the diamond layer DL on the die 120 may be substantially coplanar with the surface 150a (e.g., top surfaces) of the die 150, which is suitable for subsequent processing. In some embodiments, the surface s2 of the diamond layer DL may be further substantially coplanar with the surface 150a of the die 150 and the surface 166a of the encapsulant 166. In some embodiments, one die 120 and one die 150 are bonded to the package component 160. In alternative embodiments in which the interposer wafer is provided, each package region of the interposer wafer includes one die 120 and one die 150. In other words, there may be a plurality of dies 120 and 150 on the package component 160. Furthermore, there may be more dies to be packaged in each package region of the interposer wafer.

Referring to FIG. 12H, the package 170 is bonded to a board substrate 180, to form a package 200. The board substrate 180 may be an organic flexible substrate or a printed circuit board and include conductive connectors 182. The conductive connectors 182 may include solder bumps, and/or may include metal pillars (e.g., copper pillars), solder caps formed on metal pillars, and/or the like. The conductive connectors 182 may be formed by a suitable process such as evaporation, electroplating, ball drop, or screen printing.

In some embodiments, the diamond layer DL is disposed on the die 120 such as system-on-chips (SoC). As such, heat generated during the operation of the die 120 may be sufficiently and efficiently dissipated by the diamond layer DL. For example, the die 120 is a die generating heat more than the die 150, and the diamond layer DL sufficiently and efficiently dissipates the heat from the die 120. With the integration of the diamond layer DL, the performance and the lifetime of the die 120 and the subsequently formed package 170, 200 may be improved. In addition, in some embodiments, the diamond layer DL serves as a booster to compensate the height difference between the die 120 and another die 150 to be packaged, and thus a planarity of the formed package 170 is improved.

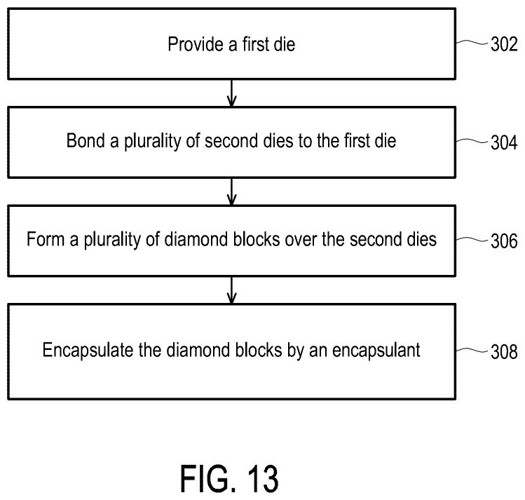

FIG. 13 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 302, a first die is provided. FIG. 1A, FIG. 2A, FIG. 3A, FIG. 4A and FIG. 5 to FIG. 10 illustrate views corresponding to some embodiments of act 302.

At act 304, a plurality of second dies are bonded to the first die. FIG. 1A, FIG. 2A, FIG. 3A, FIG. 4A and FIG. 5 to FIG. 10 illustrate views corresponding to some embodiments of act 304.

At act 306, a plurality of diamond blocks are formed over the second dies. FIG. 1F, FIG. 2A, FIG. 3B, FIG. 4A and FIG. 5 to FIG. 10 illustrate views corresponding to some embodiments of act 306.

At act 308, the diamond blocks are encapsulated by an encapsulant. FIG. 1G, FIG. 2A, FIG. 3C, FIG. 4B and FIG. 5 to FIG. 10 illustrate views corresponding to some embodiments of act 308.

In accordance with some embodiments of the disclosure, a semiconductor device includes a first die, a diamond layer and an encapsulant. The diamond layer is disposed on the first die. The encapsulant is disposed on the first die, wherein the encapsulant encapsulates the diamond layer.

In accordance with some embodiments of the disclosure, a semiconductor device includes a first die, a plurality of second dies and at least one diamond block. The second dies are bonded to the first die and encapsulated by a first encapsulant. The at least one diamond block is stacked on and thermally coupled to the second dies, wherein the second dies are disposed between the first die and the at least one diamond block.

In accordance with some embodiments of the disclosure, a method of forming a semiconductor device includes the following steps. A first die is provided. A plurality of second dies are bonded to the first die. A plurality of diamond blocks are formed over the second dies. The diamond blocks are encapsulated by an encapsulant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first die;
a diamond layer, disposed on the first die; and
an encapsulant, disposed on the first die, wherein the encapsulant encapsulates the diamond layer.

2. The semiconductor device according to claim 1, wherein a first surface of the diamond layer is substantially coplanar with a first surface of the encapsulant, and a second surface opposite to the first surface of the diamond layer is substantially coplanar with a second surface opposite to the first surface of the encapsulant.

3. The semiconductor device according to claim 1, further comprising a bonding layer between the diamond layer and the first die, wherein the encapsulant further encapsulates the bonding layer.

4. The semiconductor device according to claim 3, wherein a surface of the bonding layer is substantially coplanar with a first surface of the encapsulant and a surface of the first die, and a surface of the diamond layer is substantially coplanar with a second surface opposite to the first surface of the encapsulant.

5. The semiconductor device according to claim 1, wherein a sidewall of the encapsulant is substantially flush with a sidewall of the first die.

6. The semiconductor device according to claim 1, further comprising an interconnect substrate and a second die, wherein the first die and the second die are bonded to the interconnect structure, and a total height of the diamond layer and the first die is substantially equal to a height of the second die.

7. The semiconductor device according to claim 1, wherein sidewalls of the diamond layer are disposed between sidewalls of the first die.

8. A semiconductor device, comprising:
a first die;
a plurality of second dies bonded to the first die and encapsulated by a first encapsulant; and
at least one diamond block stacked on and thermally coupled to the second dies, wherein the second dies are disposed between the first die and the at least one diamond block.

9. The semiconductor device according to claim 8, further comprising a second encapsulant encapsulating the at least one diamond block.

10. The semiconductor device according to claim 9, wherein a sidewall of the second encapsulant is substantially flush with a sidewall of the first encapsulant and a sidewall of the first die.

11. The semiconductor device according to claim 8, wherein the at least one diamond block continuously extends over the second dies.

12. The semiconductor device according to claim 8, wherein the at least one diamond block comprises a plurality of diamond blocks, and the diamond blocks are disposed on the second dies respectively.

13. The semiconductor device according to claim 12, further comprising a second encapsulant encapsulating the diamond blocks and disposed between the diamond blocks.

14. The semiconductor device according to claim 8, wherein the at least one diamond block is stacked on the second dies along a first direction, and the at least one diamond block is overlapped with at least one of the second dies and the first die along the first direction.

15. The semiconductor device according to claim 8, further comprising a redistribution layer structure, wherein the first die is disposed between and electrically connected to the redistribution layer structure and the second dies, and the second dies are disposed between the first die and the at least one diamond block.

16. A method of forming a semiconductor device, comprising:
providing a first die;
bonding a plurality of second dies to the first die;
forming a plurality of diamond blocks over the second dies; and
encapsulating the diamond blocks by an encapsulant.

17. The method according to claim 16, further comprising:
removing portions of the first die to expose through vias of the first die;
forming a redistribution layer structure on the first die, to electrically connect to the through vias of the first die; and
after forming the redistribution layer structure, forming the diamond blocks over the second dies.

18. The method according to claim 16, further comprising:
after forming the diamond blocks, removing portions of the first die to expose through vias of the first die; and
forming a redistribution layer structure to electrically connect to the through vias of the first die.

19. The method according to claim 16, wherein forming the diamond blocks comprise disposing the diamond blocks by a pick-and-place process, a coating process or a depositing process.

20. The method according to claim 16, further comprising forming a plurality of bonding layers between the diamond blocks and the second dies respectively.
